(19) United States
(12) Patent Application Publication
(10) Pub. No.: US 2026/0024608 A1
(43) Pub. Date: Jan. 22, 2026

(54) SERVICE LIFE PREDICTION AND REPAIR METHOD FOR RESISTIVE RANDOM ACCESS MEMORY CHIP

(71) Applicant: INSTITUTE OF MICROELECTRONICS OF THE CHINESE ACADEMY OF SCIENCES, Beijing (CN)

(72) Inventors: Xiaoxin XU, Beijing (CN); Xu ZHENG, Beijing (CN); Lizhou WU, Beijing (CN); Xiaoyong XUE, Beijing (CN); Jinru LAI, Beijing (CN); Wenxuan SUN, Beijing (CN); Danian DONG, Beijing (CN)

(73) Assignee: INSTITUTE OF MICROELECTRONICS OF THE CHINESE ACADEMY OF SCIENCES, Beijing (CN)

(21) Appl. No.: 18/997,051

(22) PCT Filed: May 11, 2023
(86) PCT No.: PCT/CN2023/093388

§ 371 Date: Jan. 18, 2025

(30) Foreign Application Priority Data
Mar. 16, 2023 (CN) 202310253754.7

(51) Int. Cl. G11C 29/44

(52) U.S. Cl. CPC G11C 29/4401

(57) ABSTRACT

The present application relates to a service life prediction and repair method for a resistive random access memory (RRAM) chip. The trained model is obtained by training the model using training dataset which is constructed comprises input data X, and bicategory labeling of true failure or false failure, process the measured data of the memory unit to be predicted into nine dimensional input data then input into the trained model, obtain the prediction results of the memory unit of the last few erase-write periods, and finally determine whether or not it is a false failure memory unit that actually needs to be repaired, then performing repair operation on the false failure memory unit that actually needs to be repaired.

### CROSS-REFERENCE TO RELATED APPLICATIONS

This application claims priority to Chinese Patent Application No. 202310253754.7, filed on Mar. 16, 2023 and International Patent Application No. PCT/CN2023/093388, filed on May 11, 2023, and entitled “SERVICE LIFE PREDICTION AND REPAIR METHOD FOR RESISTIVE RANDOM ACCESS MEMORY CHIP”, both of which are hereby incorporated by reference in their entireties.

### TECHNICAL FIELD

The present application relates to the technical field of chip reliability, and particularly relates to a service life prediction and repair method for resistive random access memory chip.

### BACKGROUND

A Resistive Random Access Memory (RRAM) is an embedded non-volatile memory (NVM) that is suitable for advanced process nodes, and has the following advantages: low power consumption, high reliability and good compatibility with CMOS processes etc., which make it be provided with strong application value in IoT terminal devices. However, RRAM memory chip generally faces the following problems: write error, read interference, readout error and thermal stability etc., which increase the difficulty of the scale application of the RRAM chip. In the complex failure modes of RRAM, there are two modes of “true failure” and “false failure” as the number of continuously erasing and writing of the memory unit increases. Storage space can be allocated more efficiently by constructing a failure model to predict the failure behavior of the memory unit. For the memory unit whose predicted result is true failure, data loss can be preventable by transferring data stored in it to other memory units in advance; for the memory unit whose predicted result is false failure, a resetting voltage greater than the average voltage is applied, to “resurrect” it according to the physical mechanism of its failure, so that its conductive filaments can recover normal growth and fracture, which can improve the utilization rate of the memory unit array.

Current researches on service life prediction of the RRAM mostly focus on physical modeling of individual device, which makes the physical model based on individual device not have a high reference value for lifetime prediction of the RRAM chip, because the physical model only considers the variation of physical quantities and failure mechanism inside the memory unit and ignores the variation of devices in the RRAM chip due to the Process fluctuation. With the continuous development of machine learning (ML), ML is used to build model for the failure behavior of memory units based on statistical data, to provide a way for chip-level failure prediction. At present, there is only one article that relates to the studies on chip-level service life prediction, but the prediction accuracy is not high and there is no corresponding optimization scheme; the existing way to prevent the failure of RRAM chip units is to remediate it after a failure of the memory unit has occurred, the remedy method is also to simply increase the voltage and the storage window. As it cannot achieve prediction and repair in advance, the excessively high voltage will accelerate the aging of the memory units and will reduce the service life of the memory units instead. Therefore, there is an urgent need of a service life prediction method for resistive random access memory chip, to achieve more accurate failure prediction for resistive random access memory units at the chip level, and to realize the large-scale application of RRAM chip through better storage space allocation and repair of memory units.

### SUMMARY

In view of the above analysis, the embodiment of the present application aims at providing a service life prediction and repair method for resistive random access memory (RRAM) chip, to solve the problems that the prediction accuracy rate of the existing service life prediction of the RRAM chip models is not high and the existing repair method for a false failure memory unit is difficult to truly improve the service life of the memory unit in the RRAM chip.

In one aspect, an embodiment of the present application provides a service life prediction and repair method for a resistive random access memory chip, wherein the method comprises the following steps.

Constructing a model training dataset, the dataset comprises input data Xₜ and bicategory labeling of true failure or false failure; wherein the input data Xₜ comprises a forming voltage FVₜ, a normalized setting resistance SRₜ, a normalized resetting resistance RRₜ, local fluctuations of a setting resistance SFₜ, local fluctuations of a resetting resistance RFₜ, global fluctuations of the setting resistance SVARₜ, global fluctuations of the resetting resistance RVARₜ, an average setting voltage SVOLₜ and an average resetting voltage RVOLₜ.

Training a model M by the constructed training dataset, the model M comprises K LSTM replica models {M_{[0]}, M_{[1]}, . . . , M_{[K-1]}} with the same parameters; the different replica models are used for independent forward inference and error computation for K memory units.

Obtaining actually measured data of each memory unit to be predicted to complete read-write operations for one erase-write period under a normal working state; processing the actually measured data to obtain input data X_{pt[i]}; inputting the input data X_{pt[i]} into the corresponding trained model, to obtain a prediction result Y_{t[i]} of the memory unit for a next erase-write period t+1, and finally determine whether or not it is a false failure memory unit that actually needs to be repaired.

Obtaining an address of the false failure memory unit that actually needs to be repaired; performing repair operation on the false failure memory unit.

Further, the constructing a model training dataset comprises: obtaining the raw data Dₜ; preprocessing the raw data to obtain the input data Xₜ={FVₜ, SRₜ, RRₜ, SFₜ, RFₜ, SVARₜ, RVARₜ, SVOLₜ, RVOLₜ}, which comprises nine dimensions; constructing the dataset D₁ with data structure K×9×T based on the preprocessed 9-dimensional data; wherein K is the total number of memory units in the RRAM chip; T is the number of simulation cycles covered by the raw data; bicategory labelling the dataset D₁ as true failure or false failure to obtain the model training dataset D₂ comprising an external input Xₜ of the model M and a corresponding label Cₜ.

Further, the obtaining the raw data comprises the following steps.
(1) Performing forming operation on the RRAM chip to turn each memory unit in the chip into conduction (ON) state, and recording the forming operation voltage FV.
(2) Verifying the forming effect and recording a forming resistance Rf and an output result O of each memory unit.
(3) Performing setting operation on the formed chip, recording a resistance SR_RAW and a corresponding setting voltage SVOL_RAW, as well as the output result O of each memory unit when the setting (that is, setting a bit) is successful, or recording the resistance SR_RAW and the corresponding setting voltage SVOL_RAW, as well as the output result O of each memory unit when the setting reaches the preset times and still is unsuccessful; wherein the successful setting comprises setting success at one time, or setting success by gradually setting before not reaching the preset times.
(4) Performing resetting operation on the set chip, recording resistance RR_RAW and corresponding resetting voltage RVOL_RAW, as well as the output result O of each memory unit when resetting is successful, or recording the resistance RR_RAW and the corresponding resetting voltage RVOL_RAW, as well as the output result O of each memory unit when the resetting reaches the preset times and still is unsuccessful.
(5) Repeating the setting and resetting operations to complete the preset cycles N within one span; specifically, repeating the cycle of above steps (3)˜(4), after completing the preset cycles, recording as the completion of one span, then performing the following step (6).
(6) Repeating read operation of preset times n which is performed on the chip memory array to obtain resetting resistance sample Rᵣ for calculating fluctuations of the resetting resistance.
(7) Performing setting operation on the chip, recording the resistance Rₛₑₜ and the current setting voltage Vₛₑₜ, as well as the output result O of each memory unit when the setting is successful, or recording the resistance Rₛₑₜ and the current setting voltage Vₛₑₜ, as well as the output result O of each memory unit when the setting reaches the preset times and still is unsuccessful.
(8) Repeating read operation of the preset times n to obtain setting resistance sample Rₛ for calculating fluctuations of setting resistance.
(9) Recording above steps (3)˜(8) as one simulation cycle, repeating T simulation cycles to obtain the raw data Dₜ={FV, SVOL_RAW, RVOL_RAW, SR_RAW, RR_RAW, Rᵣ, Rₛ, Rₛₑₜ, Vₛₑₜ}ₜ.

Further, the input data Xₜ comprises the following steps.
(1) FVₜ represents the forming voltage, a value of a first time slice is FV in the raw data, all subsequent time slices are set to 0.
(2) SRₜ represents the normalized setting resistance, which is obtained through dividing an average value of the original setting resistance SR_RAW by the stable low resistance R_{low} of the RRAM; wherein R_{low} is the low resistance of the memory unit when the RRAM chip is working normally, which is also the low resistance under the most stable state.
(3) RRₜ represents the normalized resetting resistance, which is obtained through dividing an average value of the original resetting resistance RR_RAW by the stable high resistance R_{high} of the RRAM; wherein R_{high} is the high resistance of the memory unit when the RRAM chip is working normally, which is also the high resistance under the most stable state.
(4) SFₜ represents the local fluctuation of the setting resistance of the memory unit, which is obtained by normalizing the setting resistance samples and then performing convolution summation with a one-dimensional edge detection operator [−1,0, 1].
(5) RFₜ represents the local fluctuation of the resetting resistance of the memory unit, which is obtained by normalizing resetting resistance samples and then performing convolution summation with the one-dimensional edge detection operator [−1, 0, 1].
(6) SVARₜ represents the global fluctuation of the setting resistance of the memory unit, which is obtained by normalizing each resistance in the setting resistance samples and then calculating variance thereof.
(7) RVAR: represents the global fluctuation of the resetting resistance of the memory unit, which is obtained by normalizing each resistance in the resetting resistance samples and then calculating variance thereof.
(8) SVOLₜ represents the average setting voltage of the memory unit, which is obtained by averaging all the recorded setting voltages in one span of a simulation cycle.
(9) RVOLₜ represents the average resetting voltage of the memory unit, which is obtained by averaging all the recorded resetting voltages in one span of a simulation cycle.

Further, the bicategory labeling of true failure or false failure comprises the following steps.
(1) Judging a state result S_{t[i]} of the memory unit in a t+1st simulation cycle according to output result O_{t+1[i]} in each span of the t+1st simulation cycle; judgment basis is the following:
   a) when O_{t+1[i]} does not contain setting or resetting successfully, the state result S_{t+1[i]}=0, which indicates that the memory unit occurs true failure in the t+1st simulation cycle;
   b) in all cases except for i, the state result S_{t+1[i]}=1, which indicates that the memory unit occurs false failure in the t+1st simulation cycle.
(2) Labeling X_{t[i]} with corresponding label

$${c}_{t [ i ]} = {[ {c}_{i}^{0} , {c}_{i}^{1} ]}_{t}$$

according to the state result S_{t+1[i]}; wherein the superscripts 0 and 1 thereof are the index values of the two-dimensional vector; the labeling method is the following:
i. when the state result S_{t+1[i]}=0, a corresponding label of X_{t[i]} is C_{t[i]}=[1, 0]ₜ;
ii. when the state result S_{t+1[i]}=1, the corresponding label of X_{t[i]} is C_{t[i]}=[0, 1]ₜ.
(3) constructing T matrices K×2 in units of time slices as the corresponding label Cₜ of the external input Xₜ of the model M, wherein Cₜ={C_{[0]}, C_{[1]}, . . . , C_{[K-1]}}ₜ; the model training data D_{2_t} consists of Xₜ and the corresponding label Cₜ, constructing T model training data D_{2_t} in units of time slices as the model training dataset D₂, wherein D₂={D_{2_0}, D_{2_1}, . . . , D_{2_T-1}}.

Further, the model M comprises the following steps.

Constructing the model M based on the LSTM, the cell parameters comprise: cell state Cₜ, hidden state Hₜ and state update value Uₜ; the control gates comprise: forget gate FG, input gate IG and output gate OG, and formulae thereof respectively are:

$$F G = sigmoid ( {I}_{t} \times W F + B F ) ;$$

$$I G = sigmoid ( {I}_{t} \times W I + B I ) ;$$

$$O G = sigmoid ( {I}_{t} \times W O + B O ) .$$

Wherein WF, WI, WO are the weights of the forget gate, the input gate, the output gate for the affine transformation on the current neural network input Iₜ at the current time slice respectively; BF, BI, BO are offsets of the affine transformation of the forget gate, the input gate, the output gate respectively.

Further, the iterative computation of the model M comprises the following steps.
(1) Splitting the input data {D₂}ₜ of each time slice into K vectors in nine dimensions, which are input into K LSTM replica models with the same parameters respectively.
(2) Splicing a current external input X_{t[i]} of a current time slice Tₜ with a hidden state Hₜ₋₁ of a previous time slice Tₜ₋₁ to obtain a current neural network input Iₜ at the current time slice Tₜ.
(3) Affine transforming on the current neural network input Iₜ, then activating by tan h function to obtain a current state update value Uₜ.
(4) Multiplying the forget gate FG and the cell state Cₜ₋₁ of the previous time slice Tₜ₋₁ point by point, multiplying the input gate IG and the current state update value Uₜ point by point, then adding above two product results to obtain a current cell state Cₜ.
(5) Activating the current cell state Cₜ by tan h, then being multiplied with the output gate OG point by point to obtain a current hidden state Hₜ.
(6) Inputting the current hidden state Hₜ into the neural network to enter cyclic computation of a next time slice Tₜ₊₁, repeating above steps (2)˜(5), meanwhile, affine transforming the current hidden state Hₜ into two-dimensional space and being activated by softmax function to obtain a current two-dimensional vector Pₜ, taking the index value with larger value of the two elements in Pₜ as a current model output Y_{t[i]}.
(7) Splicing the two-dimensional vector Pₜ along time dimension to form an output array P of K×TS×2; splicing the label array Cₜ along the time dimension to form an output array C of K×TS×2; comparing P with C, using the cross-entropy as a loss function, formula thereof is the following:

$$L = - \frac{1}{K} {\sum }_{t = 1}^{TS} {\sum }_{= 1}^{K} {[ {c}_{i}^{1} log {p}_{i}^{1} + {c}_{i}^{0} log {p}_{i}^{0} ]}_{t} .$$

Wherein TS is a training span, value thereof is the number of time slices covered by the training set Dₜᵣₐᵢₙ; K is the total number of memory units in the RRAM chip, the data structure of a label of a single memory unit is [c⁰, c¹], i indicates the i-th memory unit, t indicates the t-th time slice.

Back propagating the loss and updating weights of the K LSTM replicas at the same time until the loss no longer decreasing to obtain K trained LSTM replicas, selecting any one of the replicas as a final model M_{trained}; wherein M_{trained}={M_{trained_[0]}, M_{trained_[1]}, . . . , M_{trained_[K-1]}}; preferably, a Adam optimizer is used for back propagating as well as weights updating of the neural network.

Further, the measured data comprising the following steps.
(1) Obtaining the forming voltage FVₚ for the forming operation of a completely new RRAM chip.
(2) Recording the actually measured data of each memory unit in each erase-write period under a normal working state of the formed RRAM chip; wherein one erase-write period comprises: the memory unit completes the setting/resetting cyclic operations of preset cycle times N, which are recorded as one span within the erase-write period; after completing one span operation within the erase-write period, performing the following steps to the memory unit: repeating read operation of preset times n, then one time resetting operation, repeating read operation of the preset times n again; the actually measured data Dₚₜ comprises: setting voltage SVOL_RAW_{p[i]} and resetting voltage RVOL_RAW_{p[i]} recorded within one span of the erase-write period, setting resistance SR_RAW_{p[i]} and resetting resistance RR_RAW_{p[i]}, resetting resistance sample R_{pr[i]} recorded by the first repeating read operation of the erase-write period, setting resistance sample R_{ps[i]} recorded by the second repeating read operation of the erase-write period, setting resistance R_{pset[i]} and setting voltage V_{pset[i]} recorded between two repeating read operations, as well as all the output results O_{p[i]} of the erase-write period.

Further, the processing the measured data to obtain input data comprises the following steps.
(1) FV_{pt[i]} represents the forming voltage of the memory unit, the value of the first erase-write endurance cycle is the forming voltage FVₚ of the chip, the values of the subsequent erase-write endurance cycles are all set to 0.
(2) SR_{pt[i]} represents the normalized setting resistance of the memory unit, which is obtained through dividing an average value of the original setting resistance SR_RAW_{pt[i]} by stable low resistance R_{low} of the RRAM.
(3) RR_{pt[i]} represents the normalized resetting resistance of the memory unit, which is obtained through dividing an average value of the original resetting resistance RR_RAW_{pt[i]} by stable high resistance R_{high} of the RRAM.
(4) SF_{pt[i]} represents the local fluctuations of the setting resistance of the memory unit, which is obtained by normalizing the setting resistance samples and then performing convolution summation with a one-dimensional edge detection operator [−1, 0, 1].
(5) RF_{pt[i]} represents the local fluctuations of the resetting resistance of the memory unit, which is obtained by normalizing the resetting resistance samples and then performing convolution summation with the one-dimensional edge detection operator [−1, 0, 1].
(6) SVAR_{pt[i]} represents the global fluctuations of the setting resistance of the memory unit, which is obtained by normalizing each resistance in the setting resistance samples and then calculating variance thereof.
(7) RVAR_{t[i]} represents the global fluctuations of the resetting resistance of the memory unit, which is obtained by normalizing each resistance in the resetting resistance samples and then calculating variance thereof.
(8) SVOL_{pt[i]} represents the average setting voltage of the memory unit, which is obtained by averaging all the recorded setting voltages in one span of the erase-write endurance cycle.
(9) RVOL_{pt[i]} represents the average resetting voltage of the memory unit, which is obtained by averaging all the recorded resetting voltages in one span of the erase-write period.

Further, the determining whether or not it is a false failure memory unit that actually needs to be repaired, comprising the following steps.
(1) The preprocessed data X_{pt[i]} after one erase-write period is input into the trained model M_{trained}.
(2) M_{trained[i]} outputs Y_{t[i]} as a prediction result of the memory unit in the next erase-write period t+1; wherein, when Y_{t[i]}=1 indicates that the unit is predicted as false failure for the next time slice, executing the following step (3); when Y_{t[i]}=0 indicates that the unit is predicted as true failure for the next time slice, transferring the data stored in it to other memory units.
(3) The prediction result of Y_{t[i]}=1 is made a secondary judgment, when the output result O_{t[i]} of the memory unit in current erase-write period t contains N+1 setting successfully and N resetting successfully, it is judged that the memory unit does not need to be repaired; otherwise, the memory unit is a false failure memory unit that actually needs to be repaired, the repair operation is carried out by a digital-to-analog converter circuit.

Further, the repair operation comprises the following steps.
(1) Gradually setting: for the i-th memory unit to be repaired, applying the setting pulse at the terminal of bit line thereof to perform the setting operation, then performing the read operation to read out resistance thereof; when the read out resistance is less than the stable low resistance R_{low} of the RRAM chip, it means that the setting operation is successful to execute the following (2); otherwise, increasing a pulse amplitude of the setting operation gradually in a preset increase value, repeating the setting and read operation cycles until the setting and read operations reach the preset number of cycle times or the resistance read out by the read operation is less than the stable low resistance R_{low} of the RRAM chip.
(2) Resetting repair: for the i-th memory unit to be repaired, apply the resetting pulse higher than the average resetting voltage of the current erase-write period at the terminal of source line thereof to perform the resetting operation, then performing the read operation to read out resistance thereof; the amplitude of the resetting pulse voltage is RVOL_{pt[i]}+the preset increase value; wherein RVOL_{pt[i]} is the average voltage of N resetting operations of the memory unit within a span of the current erase-write period.
(3) repeating the repair cycle of above steps (1) and (2) until he cumulative preset number of repair cycles is reached to complete the repair operation of the memory unit.

Compared with existing technology, the present application achieves at least one of the following beneficial effects.
1. The model input using nine-dimensional data, wherein three parameters SVOLₜ, RVOLₜ, FVₜ, which are related to voltage, contain key external operation information of the RRAM chip, the six parameters SRₜ, RRₜ, SFₜ, RFₜ, SVARₜ, RVARₜ, which are related to resistance, contain main physical state information of the memory unit of the RRAM chip, which fits well with a physical model of RRAM resistive variation process, the time series model constructed based on them is more scientific and effective; wherein two sets of feature quantities SFₜ/RFₜ, SVAR_{/}RVARₜ are used to represent the local fluctuations and global fluctuations of the resistance respectively, the random fluctuations and jumping properties of the resistance of the RRAM is included in the inputs of the model, so the physical state of the RRAM device is reflected more comprehensively.
2. according to the prediction results of the model, a specific voltage excitation is applied to the memory unit which may occur false failure and the amplitude of the voltage is gradually increased to prevent the occurrence of false failure. Compared with the existing way of remedying false failure after it has occurred in the memory unit and the remedy way of simply increasing the voltage and the storage window, the method provided by the present application will not accelerate the aging of the memory unit and reduce the service life of the memory unit due to the excessively high voltage, and can significantly reduce the error rate of the memory unit of the RRAM chip.
3. The prediction accuracy rate of the model constructed using the method provided by the present application reaches 86.75%, which is much higher than 65% of the existing prediction model; at the same time, compared with the drawback of the existing model that has too many setting/resetting operations in one prediction cycle, the model of the present application realizes the prediction of the memory unit under fewer setting/resetting operations. That is, one prediction cycle of the existing model needs to include 100,000 setting/resetting operations, while the model of the present application can reduce the prediction cycles to 500 setting/resetting operations, which can achieve prediction and repair of the memory unit more timely.

In the present application, the above technical solutions can be combined, to implement more preferred combined solutions. Other features and advantages of the present application will be described in the subsequent specification, and part of the advantages can become apparent from the specification, or be understood through the implementation of the present application. The objects and other advantages of the present application can be implemented and obtained from the contents particularly illustrated in the specification and the drawings.

### BRIEF DESCRIPTION OF DRAWINGS

The drawings are merely for the purpose of illustrating the particular embodiments, and are not considered as limitation to the present application. Throughout the drawings, the same reference signs denote the same elements.

FIG. 1 is a flow diagram of a service life prediction and repair method for a resistive random access memory chip according to an embodiment of the present application.

FIG. 2 is a structure schematic diagram of a memory unit and array of the RRAM chip according to an embodiment of the present application.

FIG. 3 is a flow diagram of the raw data acquisition according to an embodiment of the present application.

FIG. 4 is an overall schematic diagram of the LSTM architecture according to an embodiment of the present application.

FIG. 5 is a schematic diagram of the model training based on the LSTM according to an embodiment of the present application.

FIG. 6 is a schematic diagram of a prediction method of a service life model of the RRAM chip according to an embodiment of the present application.

FIG. 7 is a schematic diagram of the repair voltage applied to the memory unit of false failure according to an embodiment of the present application.

FIG. 8 is a schematic diagram of the morphology of the conductive filaments of the memory unit during the repair method applied according to an embodiment of the present application.

FIG. 9 is a flow diagram of repair method of false failure memory unit according to an embodiment of the present application.

FIG. 10 is a histogram of the statistical results of the prediction accuracy rate of the prediction task model comprising different time slices according to an embodiment of the present application.

FIG. 11 is a repair rate of the memory unit where false failure occurs in different resistance intervals before and after applying the repair method and an improvement rate of the repair rate according to an embodiment of the present application.

FIG. 12 is the probability of occurring false failure in different resistance intervals before and after applying the repair method and a decrease rate of the probability of occurring the false failure according to an embodiment of the present application.

### DESCRIPTION OF EMBODIMENTS

The preferable embodiments of the present application will be particularly described below by referring to the drawings. The drawings form part of the present application, are used to explain the principle of the present application together with the embodiments of the present application, and are not limiting the scope of the present application.

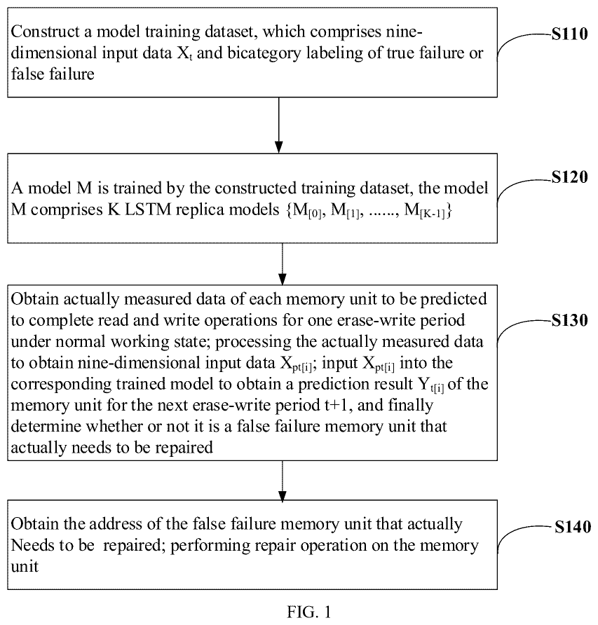

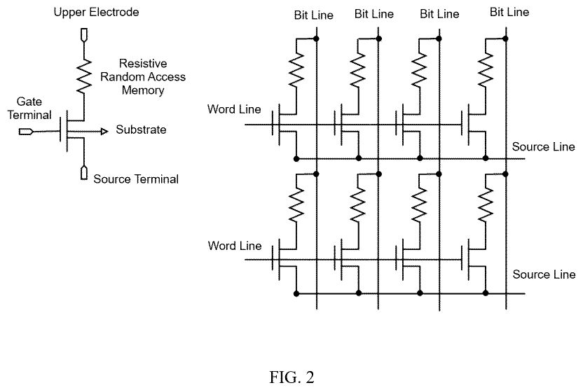

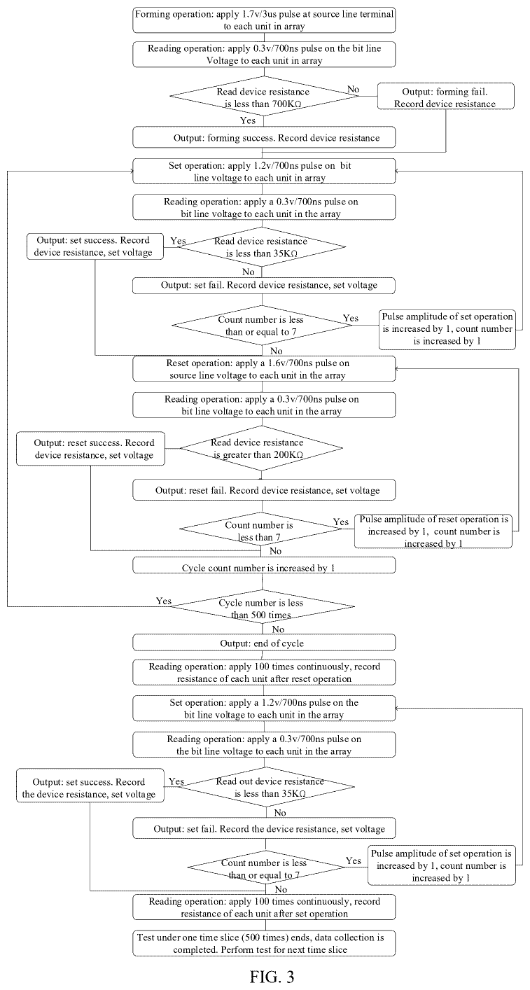

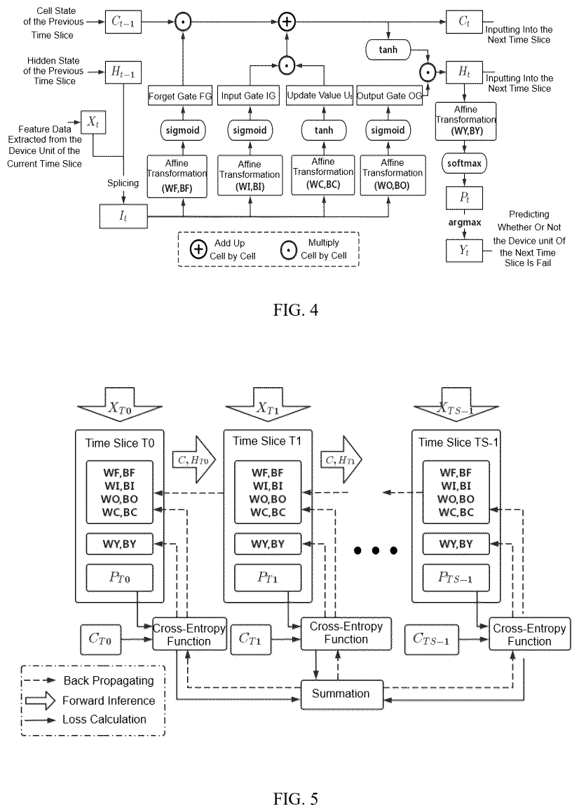

A particular embodiment of the present application discloses a service life prediction and repair method for a resistive random access memory (RRAM) chip, as shown in FIG. 1, comprising the following steps.

Step S110, construction steps of a model training dataset: obtaining raw data of all memory units of a RRAM chip in a plurality of simulation cycles; the simulation cycle is a cycle that simulates actually erase-write process of the RRAM chip to evaluate endurance; preprocessing the raw data to obtain input data in nine dimensions Xₜ={FVₜ, SRₜ, RRₜ, SFₜ, RFₜ, SVARₜ, RVARₜ, SVOLₜ, RVOLₜ}, which comprises a forming voltage FVₜ, a normalized setting resistance SRₜ, a normalized resetting resistance RRₜ, local fluctuations of a setting resistance SFₜ, local fluctuations of a resetting resistance RFₜ, global fluctuations of the setting resistance SVARₜ, global fluctuations of the resetting resistance RVARₜ, an average setting voltage SVOLₜ and an average resetting voltage RVOLₜ measured by sensors, such as a voltage oscilloscope, a current oscilloscope etc.; constructing Xₜ into a dataset D₁ with data structure K×9×T and storing in a database of a network server; wherein K is the total number of memory units in the RRAM chip, Tis the number of simulation cycles covered by the raw data; bicategory labeling the dataset D₁ as true failure or false failure according to output results within one span of each simulation cycle, to obtain a model training dataset D₂ comprising external inputs Xₜ of a model M and corresponding label Cₜ; wherein one span of the simulation cycle is N setting-resetting cycle operations.

Step S120, training step of the model: dividing the model training dataset into training set Dₜᵣₐᵢₙ and test set Dₜₑₛₜ; initializing the model M and constructing M into K LSTM replica models {M_{[0]}, M_{[1]}, . . . , M_{[K-1]}} with the same parameters; the different replica models are used for independent forward inference and error computation for K memory units; training the model M using the training set Dₜᵣₐᵢₙ to obtain a final model M_{trained}, testing the model M_{trained} using the test set Dₜₑₛₜ.

Step S130, prediction steps of the model: obtaining actually measured data of each memory unit to complete read-write operations of one erase-write period under a normal working state by a read-write circuit; wherein the erase-write period is a cycle that evaluate endurance of the memory unit after a certain number of erase-write times under the normal working state of the RRAM chip; preprocessing the actually measured data to obtain input data in nine dimensions X_{pt[i]}={FV_{p[i]}, SR_{p[i]}, RR_{p[i]}, SF_{p[i]}, RF_{p[i]}, SVAR_{p[i]}, RVAR_{p[i]}, SVOL_{p[i]}, RVOL_{p[i]}}ₜ of the memory unit in current erase-write period t; inputting X_{pt[i]} into corresponding trained model M_{trained} to obtain a prediction result Y_{t[i]} of the memory unit for the next erase-write period t+1, and finally determine whether or not it is a false failure memory unit that actually needs to be repaired.

Step S140, repairing steps of the memory unit: obtaining an address of the false failure memory unit that actually needs to be repaired; performing repair operation on the memory unit; the memory unit enters the next erase-write period.

Specifically, constructing the model training dataset in step S110 comprises the following steps.
1. Obtaining the raw data Dₜ={D_{t[0]}, D_{t[1]}, . . . , D_{t[K-1]}}, wherein D_{t[i]=}{FV, SVOL_RAW_{[i]}, RVOL_RAW_{[i]}, SR_RAW_{[i]}, RR_RAW_{[i]}, R_{r[i]}, R_{s[i]}, R_{set[i]}, V_{set[i]}}ₜ, t indicates the t-th simulation cycle, t∈[0, T−1], i indicates the i-th memory unit, i∈[0, K−1]; K is total number of memory units in the RRAM chip.

Specifically, FV indicates the forming operation voltage;

$${SVOL\_RAW}_{t [ i ]} = {\{ {SVOL\_RAW}_{[ i ]}^{0} , {SVOL\_RAW}_{[ i ]}^{1} , … , {SVOL\_RAW}_{[ i ]}^{N - 1} \}}_{t} ,$$

$${RVOL\_RAW}_{t [ i ]} = {\{ {RVOL\_RAW}_{[ i ]}^{0} , {RVOL\_RAW}_{[ i ]}^{1} , … , {RVOL\_RAW}_{[ i ]}^{N - 1} \}}_{t} ,$$

respectively represent the setting voltage and resetting voltage of the N setting-resetting cycle operations of each memory unit in one span of each simulation cycle among all TS simulation cycles;

$${SR\_RAW}_{t [ i ]} = {\{ {SR\_RAW}_{[ i ]}^{0} , {SR\_RAW}_{[ i ]}^{1} , … , {SR\_RAW}_{[ i ]}^{N - 1} \}}_{t} ,$$

$${RR\_RAW}_{t [ i ]} = {\{ {RR\_RAW}_{[ i ]}^{0} , {RR\_RAW}_{[ i ]}^{1} , … , {RR\_RAW}_{[ i ]}^{N - 1} \}}_{t} ,$$

respectively represent N original setting resistances and N original resetting resistances being read after the N setting-resetting cycle operations of each memory unit in one span of each simulation cycle among all TS simulation cycles;

$${R}_{rt [ i ]} = {\{ {R}_{r [ i ]}^{0} , {R}_{r [ i ]}^{1} , … , {R}_{r [ i ]}^{n - 1} \}}_{t} , {R}_{st [ i ]} = {\{ {R}_{s [ i ]}^{0} , {R}_{s [ i ]}^{1} , … , {R}_{s [ i ]}^{n - 1} \}}_{t}$$

respectively represent the resetting resistance obtained via n continuous read operations after each memory unit passing one span operations, and setting resistance obtained via the n continuous read operations after passing one setting operation again, in each simulation cycle among all T simulation cycles; wherein t∈[0, T−1], indicates the t-th simulation cycle, i indicates the i-th memory unit, i∈[0, K−1]; K is the total number of memory units in the RRAM chip.

Specifically, the raw data Dₜ is obtained by read-write circuit using test software and performing the following steps.
(1) Performing a forming operation on the RRAM chip to turn each memory unit in the chip into conduction state using a pulse of a forming voltage which is provided by generating a setting voltage or resetting voltage by a setting/resetting device and converting the setting voltage or resetting voltage into the forming voltage by a voltage converter, and recording a forming operation voltage FV by a recording device; specifically, performing a forming operation on a completely new RRAM chip, applying pulses of the forming operation voltage to source line terminal (SL terminal) of the chip memory array to turn each memory unit in the chip into the conduction state, recording the forming voltage FV=1.7V; wherein the forming operation voltage FV is set according to the forming operation voltage of the chip when actually predicting, range thereof is 1.5 v˜2.5 v; preferably, the pulses of the forming operation voltage are 1.7V/3 us and FV=1.7 v.
(2) Verifying the forming effect and recording the forming resistance R_{f} as well as the output result O of each memory unit; specifically, verifying the forming effect through the read operation, applying the read operation voltage to the bit line terminal (BL terminal) of the chip memory array, reading out the resistance of each memory unit, judging whether or not it is in the range of the resistance for successfully forming operation; when the read out resistance is in the range of the resistance for successfully forming operation, the output result O_{[i]} is forming success and the resistance R_{f[i]} is recorded, then the following step (3) is executed; otherwise, the output result O_{[i]} is forming fail and the resistance R_{f[i]} is recorded, then the following step (3) is executed; wherein i indicates the i-th memory unit; optionally, outputting the forming success, when the read out resistance of the device is reduced from MΩ level to KΩ level; preferably, the resistance range of the forming operation success is below 700 KΩ; wherein the read operation voltage is set according to the read operation voltage of the chip when actually predicting, range thereof is 0.1 v˜0.4 v; preferably, the read operation voltage is 0.3 v.
(3) Setting the formed chip using a pulse of the setting voltage by the setting/resetting device, recording the resistance SR_RAW and the corresponding setting voltage SVOL_RAW, as well as the output result O of each memory unit by the recording device when setting success, or recording the resistance SR_RAW and the corresponding setting voltage SVOL_RAW, as well as the output result O of each memory unit when setting reaches the preset times and still is unsuccessful; wherein the setting success includes setting success at one time or setting success by gradually setting before not reaching the preset times; specifically, comprising the following steps a˜c.
a. Performing setting (set) operation on the formed chip memory array, applying the pulses of the setting operation voltage to the bit line terminal (BL terminal) of the memory unit to be setting of the chip memory array; wherein the initial value of the setting operation voltage is set according to the initial value of the setting operation voltage of the chip when actually predicting, the initial memory units to be setting are all memory units, the range of the setting operation voltage is 0.8 v˜2.5 v; preferably, the initial setting operation voltage is the setting operation voltage that enables the RRAM chip to work stably, the pulses of the initial setting operation are 1.2 v/700 ns.
b. Verifying setting validity, recording the resistance and the current setting voltage of each memory unit when setting success; reading out the resistance of the memory unit after setting via above step a through read operation, judging whether or not it is in the range of resistance under the condition of setting success; when the read out resistance is in the resistance range under the condition of setting validity, the output result O_{[i]} is the setting success, the resistance SR_RAW_{[i]} and the current setting voltage SVOL_RAW_{[i]} is recorded, wherein i indicates the i-th memory unit, the following step (4) is executed; otherwise, the memory unit is still a memory unit to be set, the following step c is executed; preferably, the range of resistance under the condition of setting success is less than the stable low resistance R_{low}; wherein R_{low} is the low resistance of the memory unit when the RRAM chip is working normally, and also is the low resistance under the most stable state, preferably, the value of R_{low} is 35 kΩ.
c. Setting gradually till setting fail, recording the resistance and the current setting voltage of each memory unit when setting fail; specifically, setting gradually, increasing the current value of the setting operation voltage by the preset increasing value one by one, repeating above steps a, b until the gradually setting operation reaches the preset times, the output result O_{[i]} is setting fail, recording the resistance

$${SR\_RAW}_{[ 1 ]}^{0}$$

and the current setting voltage

$${SVOL\_RAW}_{[ 1 ]}^{0} ,$$

executing the following step (4); wherein i indicates the i-th memory unit, i∈[0, K−1]; K is the total number of memory units in the RRAM chip; optionally, the preset increase value is 1˜10 integer multiples of 0.05 v; preferably, the preset increase value is 0.1 v, the preset times of the gradually setting operation is 7 times.
(4) Resetting the formed chip using a pulse of a resetting voltage by the setting/resetting device, recording the resistance RR_RAW and the corresponding resetting voltage RVOL_RAW, as well as the output result O of each memory unit when resetting success, or recording the resistance RR_RAW and the corresponding resetting voltage RVOL_RAW, as well as the output result O of each memory unit when resetting reaches the preset times and still is unsuccessful; wherein the resetting success includes resetting success at one time or resetting success by gradually resetting before not reaching the preset times. Specifically, comprising the following steps a˜c.
a. Performing resetting operation on the chip memory array, applying the pulses of the resetting voltage to the source line terminal (SL terminal) of the memory unit to be reset; wherein the initial value of the resetting voltage is set according to the initial value of the resetting operation voltage of the chip during actual prediction, the initial memory units to be set are all memory units, the range of the resetting operation voltage is 1V˜3V; preferably, the initial resetting operation voltage is the setting operation voltage that enables the RRAM chip to work stably, pulses of the initial resetting operation are 1.6V/700 ns.
b. Verifying resetting validity, recording the resistance and the current resetting voltage of each memory unit when resetting success; read out the resistance of each memory unit after resetting via above step a through read operation, judging whether or not it is in the range of resistance under the condition of resetting success; when the read out resistance is in the resistance range under the condition of resetting validity, the output result O_{[i]} being resetting success, recording the resistance

$${RR\_RAW}_{[ 1 ]}^{0}$$

and the current resetting voltage

$${RVOL\_RAW}_{[ 1 ]}^{0} ,$$

wherein I indicates the i-th memory unit, i∈[0, K−1]; K is the total number of memory units in the RRAM chip, the following step (5) is executed; otherwise, the following step c is executed; preferably, the range of resistance under the condition of resetting success is greater than the stable high resistance R_{high}; wherein R_{high} is the high resistance of the memory unit when the RRAM chip is working normally, and also is the high resistance under the most stable state, preferably, the value of R_{high} is 200KΩ.
c. Resetting gradually till resetting fail, recording the resistance and the current resetting voltage of each memory unit when resetting fail; specifically, resetting gradually, increasing the current value of the resetting operation voltage in a preset increase value, repeating above steps a, b until the gradually resetting operation reaches the preset times, the output result O_{[i]} is resetting fail, recording the resistance

$${RR\_RAW}_{[ i ]}^{0}$$

and the current reset voltage

$${RVOL\_RAW}_{[ i ]}^{0} ,$$

then executing the following step (5); wherein i indicates the i-th memory unit, i∈[0, K−1]; K is the total number of memory units in the RRAM chip; optionally, the preset increase value is 1˜10 integer multiples of 0.05 v; preferably, the preset increase value is 0.1 v, the preset times of the gradually resetting operation is 7 times.
(5) Repeating the setting and resetting operations to complete the preset cycles N within one span; specifically, repeating cycle of above steps (3)˜(4), after completing the preset cycles, it is recorded as the completion of one span, executing the following step (6); preferably, the preset number of cycles is set to 500.
(6) Repeating read operation of preset times n which is performed on the chip memory array to obtain resetting resistance sample Rᵣ for calculating resetting resistance fluctuations; specifically, reading out and recording the resistance of all the memory units using read operation, repeat for n times to obtain n resistance records of each memory unit; wherein the value of n is to be a compromise between being able to obtain the resistance fluctuations and reducing the influence on the service life of the memory unit; preferably, the value of n is 100,

$${R}_{{r [ i ]}^{=}}^{100} \{ {R}_{r [ i ]}^{0} , {R}_{r [ i ]}^{1} , … … , {R}_{r [ i ]}^{99} \} ;$$

wherein i indicates the i-th memory unit, i∈[0, K−1]; K is the total number of memory units in the RRAM chip.
(7) Setting the chip, recording the resistance Rₛₑₜ and the current setting voltage Vₛₑₜ, as well as the output result O of each memory unit when setting success, or recording the resistance Rₛₑₜ and the current setting voltage Vₛₑₜ, as well as the output result O of each memory unit when setting reaches the preset times and still is unsuccessful; wherein the setting success includes setting success at one time or setting success by gradually setting before not reaching the preset times. Specifically, comprising the following steps a˜c.
a. Performing setting operation on the chip memory array, applying the pulses of the setting operation voltage to the bit line terminal (BL terminal) of the memory unit to be setting of the chip memory array; wherein the initial value of the setting operation voltage is set according to the initial value of the setting operation voltage of the chip during actual prediction, the initial memory units to be setting are all memory units, the range of the setting operation voltage is 0.8 v˜2.5 v; preferably, pulses of the initial setting operation are 1.2 v/700 ns.
b. Verifying setting validity, recording the resistance and the current setting voltage of each memory unit when setting success; reading out the resistance of each memory unit after setting via above step a through read operation, judging whether or not it is in the range of resistance under the condition of setting success; when the read out resistance is in the resistance range under the condition of setting validity, the output result O_{[i]} is setting success, the resistance

$${R}_{set [ i ]}^{0}$$

and the current setting voltage

$${V}_{set [ i ]}^{0}$$

is recorded, wherein i indicates the i-th memory unit, to execute the following step (8); otherwise, the memory unit is still a memory unit to be setting, to execute the following step c; preferably, the range of resistance under the condition of setting success is less than the stable low resistance R_{low}; wherein R_{low} is the low resistance of the memory unit when the RRAM chip is working normally, and also is the low resistance under the most stable state, preferably, the value of R_{low} is 35 kΩ.
c. Setting gradually till setting fail, recording the resistance Rₛₑₜ and the current setting voltage Vₛₑₜ of each memory unit when setting fail; specifically, setting gradually, increasing the current value of the setting operation voltage in the preset increase value one by one, repeating a, b until the gradually setting operations reach the preset times, the output result O_{[i]} is setting fail, the resistance R_{set[i]} and the current setting voltage V_{set[i]} is recorded, to execute the following step (8); wherein i indicates the i-th memory unit, i∈[0, K−1]; K is the total number of memory units in the RRAM chip; optionally, the preset increase value is 1˜10 integer multiples of 0.05 v; preferably, the preset increase value is 0.1 v, the preset times of the gradually setting operation is 7 times.
(8) Repeating read operation of preset times n to obtain setting resistance sample Rs for calculating setting resistance fluctuations; specifically, reading out and recording the resistance of all the memory units using read operation, repeat for n times to obtain n resistance records of each memory unit; wherein the value of n is to be a compromise between being able to obtain the resistance fluctuations and reducing the influence on the service life of the memory unit; preferably, the value of n is 100,

$${R}_{s [ i ]}^{100} = \{ {R}_{s [ i ]}^{0} , {R}_{s [ i ]}^{1} , … … , {R}_{s [ i ]}^{99} \} ;$$

wherein i indicates the i-th memory unit, i∈[0, K−1]; K is the total number of memory units in the RRAM chip.
(9) Recording above steps (3)˜(8) as one simulation cycle, repeat for T simulation cycles to obtain the raw data Dₜ={FV, SVOL_RAW, RVOL_RAW, SR_RAW, RR_RAW, Rᵣ, Rₛ, Rₛₑₜ, Vₛₑₜ}ₜ; preferably, when the preset cycles N of one span is 500 and the preset number of repeated read operations n after one span is 100,

$${D}_{t [ i ]} = {\{ F V , {SVOL\_RAW}_{[ i ]}^{500} , {RVOL\_RAW}_{[ i ]}^{500} , {SR\_RAW}_{[ i ]}^{500} , {RR\_RAW}_{[ i ]}^{500} , {R}_{r [ i ]}^{100} , {R}_{s [ i ]}^{100} , {R}_{s e t [ i ]} , {V}_{s e t [ i ]} \}}_{t} ,$$

wherein t indicates the t-th simulation cycle, t∈[0, T−1], i indicates the i-th memory unit, i∈[0, K−1]; K is the total number of memory units in the RRAM chip; preferably, obtain the raw data of 25 simulation cycles, that is, T=25.

The one span operation of one simulation cycle is used to simulate RRAM chip erase-write process and to determine the preset number of cycles according to endurance assessment requirements; the repeat operation after one span is used to obtain resistance data sample for calculating resistance fluctuations.

Optionally, the RRAM chip is placed on the test board of the chip test machine, completing acquisition of raw data using test software to realize automatic acquisition of the raw data.

Optionally, the model number of the chip test machine may be ADVANTEST V93000.
2. Preprocessing the raw data to obtain the input data Xₜ={FVₜ, SRₜ, RRₜ, SFₜ, RFₜ, SVARₜ, RVARₜ, SVOLₜ, RVOLₜ}, which comprises nine dimensions, the steps comprises the following contents.
(1) FVₜ represents the forming voltage, the value of the first time slice is FV in the raw data, all subsequent time slices are set to 0; the time slices are the intervals with equal cycles on the time axis of the RRAM chip service life model, the t-th time slice corresponds to the read operation as well as the setting and resetting operations of the t-th simulation cycle under the simulation environment, and the time slice when the device is just shipped out of the factory after the forming operation is T0, followed by T₁, T₂, . . . , Tₜ, . . . , T_{T-1}; specifically, FVₜ={FV_{[1]}, FV_{[2]}, . . . , FV_{[K-1]}}ₜ, wherein t=0 is the first time slice T0 of the training model, FV₀={FV_{[0]}, FV_{[1]}, . . . , FV_{[K-1]}}₀; t∈[1, T−1] is the second to the (T−1)-th time slices of the training model, FVₜ={FV_{[1]}, FV_{[2],} . . . , FV_{[K]}}ₜ=0.
(2) SRₜ represents the normalized setting resistance, which is obtained through dividing an average value of the original setting resistance SR_RAW by the stable low resistance R_{low} of RRAM; wherein R_{low} is the low resistance of the memory unit when the RRAM chip is working normally, which is also the low resistance under the most stable state; the value of R_{low} is 35 kΩ in this embodiment; specifically, SRₜ={SR_{[0]}, SR_{[1]}, . . . , SR_{[K-1]}}ₜ, wherein SR_{t[i]} is the normalized setting resistance of the t-th cycle of the i-th memory unit, formula thereof is:

$$S {R}_{t [ i ]} = \frac{1}{N} \frac{1}{{R}_{low}} {\sum }_{j} {\{ {SR\_RAW}_{[ i ]}^{j} \}}_{t} .$$

Wherein i indicates the i-th memory unit, i∈[0, K−1]; j indicates the j-th setting operation in one span, j∈[0, N−1]; t indicates the t-th simulation cycle or the t-th time slice in the simulation environment, t∈[0, T−1]; K is the total number of memory units in the RRAM chip, T is the number of simulation cycles covered by the raw data; N is the number of cycles of the completed setting-resetting cycle operations of memory unit in one span of simulation cycle.
(3) RRₜ represents the normalized resetting resistance, which is obtained through dividing an average value of the original resetting resistance RR_RAW by the stable high resistance R_{high} of the RRAM; wherein R_{high} is the high resistance of the memory unit when the RRAM chip is working normally, which is also the high resistance under the most stable state; the value of the stable high resistance R_{high} is 200 kΩ in this embodiment; specifically, RRₜ={RR_{[0]}, RR_{[1]}, RR_{[K-1]}}ₜ, wherein RR_{t[i]} is the normalized resetting resistance of the t-th cycle of the i-th memory unit of the original resetting resistance RR_RAW_{t[i]}, formula thereof is:

$$R {R}_{t [ i ]} = \frac{1}{N} \frac{1}{{R}_{high}} {\sum }_{m} {\{ {RR\_RAW}_{[ i ]}^{m} \}}_{t} .$$

Wherein i indicates the i-th memory unit, i∈[0, K−1]; m indicates the m-th resetting operation in one span, m∈[0, N−1]; t indicates the t-th simulation cycle or the t-th time slice in the simulation environment, t∈[0, T−1]; K is the total number of memory units in the RRAM chip, T is the number of simulation cycles covered by the raw data; N is the number of cycles of the completed setting-resetting cycle operations of memory unit in one span of simulation cycle.
(4) SFₜ represents the local fluctuations of the setting resistance of the memory unit, which is obtained by normalizing the setting resistance samples, then performing convolution summation with a one-dimensional edge detection operator [−1, 0, 1]; specifically, Rₛ={SF_{[0]}, SF_{[1]}, . . . , SF_{[K-1]}}ₜ, wherein SF_{t[i]} is the local fluctuations of the setting resistance sample R_{st[i]} obtained via the n continuous read operations after one span in each simulation cycle of the memory unit, then via the n continuous read operations after one more setting operation, which is obtained by normalizing R_{st[i]}, then performing convolution summation with a one-dimensional edge detection operator [−1, 0, 1], formula thereof is:

$$\begin{matrix}{R}_{{s}^{′} t [ i ]} = {R}_{s t [ i ]} / {R}_{l o w} ; \\ δ = [ - 1 , 0 , 1 ] ; \\ {SF}_{t [ i ]} = \sum δ ⊗ {\{ {R}_{{s}^{′} [ i ]} \}}_{t} ; \\ {SF}_{t} = {\{ S {F}_{[ 1 ]} , S {F}_{[ 2 ]} , … … , {SF}_{[ K - 1 ]} \}}_{t} .\end{matrix}$$

Wherein

$${R}_{st [ i ]} = {\{ {R}_{s [ i ]}^{0} , {R}_{s [ i ]}^{1} , …… , {R}_{s [ i ]}^{n - 1} \}}_{t} ;$$

t indicates the t-th simulation cycle or the t-th time slice in the simulation environment, t∈[0, T−1]; K is the total number of memory units in the RRAM chip, T is the number of simulation cycles covered by the raw data; n is the number of samples of the setting resistance R_{st[i]} obtained by repeated read operations after one span in the simulation cycle.
(5) RFₜ represents the local fluctuations of the resetting resistance of the memory unit, which is obtained by normalizing the resetting resistance samples, then performing convolution summation with a one-dimensional edge detection operator [−1, 0, 1]; specifically, RFₜ={RF_{[0]}, RF_{[1]}, . . . , RF_{[K-1]}}ₜ, wherein RF_{t[i]} represents the local fluctuations of the resistance R_{rt[i]} obtained via the n continuous read operations after one span in each simulation cycle of the memory unit, which is obtained by normalizing R_{rt[i]}, then performing convolution summation with a one-dimensional edge detection operator [−1, 0, 1], formula thereof is:

$$\begin{matrix}{R}_{{r}^{′} t [ i ]} = {R}_{rt [ i ]} / {R}_{h i g h} ; \\ δ = [ - 1 , 0 , 1 ] ; \\ {RF}_{t [ i ]} = \sum δ ⊗ {\{ {R}_{{r}^{′} [ i ]} \}}_{t} ; \\ {RF}_{t} = {\{ R {F}_{[ 1 ]} , R {F}_{[ 2 ]} , …… , {RF}_{[ K - 1 ]} \}}_{t} .\end{matrix}$$

Wherein

$${R}_{rt [ i ]} = {\{ {R}_{r [ i ]}^{0} , {R}_{r [ i ]}^{1} , …… , {R}_{r [ i ]}^{n - 1} \}}_{t} ;$$

t indicates the t-th simulation cycle or the t-th time slice in the simulation environment, t∈[0, T−1]; K is the total number of memory units in the RRAM chip, T is the number of simulation cycles covered by the raw data; n is the number of samples of the resetting resistance R_{rt[i]} obtained by repeated read operations after one span in the simulation cycle.
(6) SVARₜ represents the global fluctuations of the setting resistance of the memory unit, which is obtained by normalizing each resistance in the setting resistance samples and then calculating variance thereof; specifically, SVARₜ={SVAR_{[0]}, SVAR_{[1]}, . . . , SVAR_{[K-1]}}ₜ, wherein SVARₜ represents the global fluctuations of the resistance R_{st[i]} obtained via the n continuous read operations after one span in each simulation cycle of the memory unit, then via the n continuous read operations after one setting operation, which is obtained by normalizing each resistance in R_{st[i]} and then calculating variance thereof, formula thereof is:

$$\begin{matrix}{R}_{{s}^{′} t [ i ]} = {R}_{st [ i ]} / {R}_{l o w} ; \\ S {VAR}_{t [ i ]} = \{ \frac{{\sum }_{k} {( {R}_{{s}^{′} [ i ]}^{k} - \frac{{\sum }_{k} ( {R}_{{s}^{′} [ i ]}^{k}}{n} )}^{2}}{n} \} ; \\ {S VAR}_{t} = {\{ S {VAR}_{[ 1 ]} , S {VAR}_{[ 2 ]} , …… , S {VAR}_{[ K - 1 ]} \}}_{t} .\end{matrix}$$

Wherein,

$${R}_{st [ i ]} = {\{ {R}_{s [ i ]}^{0} , {R}_{s [ i ]}^{1} , …… , {R}_{s [ i ]}^{n - 1} \}}_{t} ;$$

t indicates the t-th simulation cycle or the t-th time slice in the simulation environment, t∈[0, T−1]; K is the total number of memory units in the RRAM chip, T is the number of simulation cycles covered by the raw data; k indicates the k-th read operation from the n continuous read operations after one setting operation which is after the n continuous read operations, after one span in each simulation cycle of the memory unit; n is the number of samples of the setting resistance R_{st[i]} obtained by repeated read operations after one span in the simulation cycle.
(7) RVARₜ represents the global fluctuations of the resetting resistance of the memory unit, which is obtained by normalizing each resistance in the resetting resistance samples and then calculating variance thereof; specifically, RVARₜ={RVAR_{[0]}, RVAR_{[1]}, . . . , RVAR_{[K-1]}}ₜ, wherein RVARₜ represents the global fluctuations of the resistance R_{rt[i]} obtained via the n continuous read operations, after one span in each simulation cycle of the memory unit, which is obtained by normalizing each resistance in R_{rt[i]} and then calculating variance thereof, formula thereof is:

$${R}_{{r}^{′} t [ i ]} = {R}_{rt [ i ]} / {R}_{high} ;$$

$${RVAR}_{t [ i ]} = {\{ \frac{{\sum }_{l} {( {R}_{{r}^{′} [ i ]}^{1} \frac{{\sum }_{l} {R}_{{r}^{′} [ i ]}^{1}}{n} )}^{2}}{n} \}}_{t} ;$$

$${RVAR}_{t} = {\{ {RVAR}_{[ 1 ]} , {RVAR}_{[ 2 ]} , … , {RVAR}_{[ K - 1 ]} \}}_{t} .$$

Wherein

$${R}_{rt [ i ]} = {\{ {R}_{r [ i ]}^{0} , {R}_{r [ i ]}^{1} , … , {R}_{r [ i ]}^{n - 1} \}}_{t} ;$$

t indicates the t-th simulation cycle or the t-th time slice in the simulation environment, t∈[0, T−1]; K is the total number of memory units in the RRAM chip, T is the number of simulation cycles covered by the raw data; I indicates the I-th read operation from the n continuous read operations after one span in each simulation cycle of the memory unit; n is the number of samples of the resetting resistance R_{rt[i]} obtained by repeated read operations after one span in the simulation cycle.
(8) SVOLₜ represents the average setting voltage of the memory unit, which is obtained by averaging all the recorded setting voltages in one span of an simulation cycle; specifically, SVOLₜ={SVOL_{[0]}, SVOL_{[1]}, . . . , SVOL_{[K-1]}}ₜ, wherein SVOLₜ represents the average setting voltage of the setting operations of one span operation in the t-th simulation cycle of the memory unit, formula thereof is:

$${S VOL}_{t [ i ]} = \frac{1}{N} {\sum }_{J} {\{ {SVOL\_RAW}_{[ i ]}^{j} \}}_{t} .$$

Wherein i indicates the i-th memory unit, i∈[0, K−1]; j indicates the j-th setting operation in one span, j∈[0, N−1]; t indicates the t-th simulation cycle or the t-th time slice in the simulation environment, t∈[0, T−1]; K is the total number of memory units in the RRAM chip, T is the number of simulation cycles covered by the raw data; N is the number of cycles of the completed setting-resetting cycle operations of memory unit in one span of simulation cycle.
(9) RVOLₜ represents the average resetting voltage of the memory unit, which is obtained by averaging all the recorded resetting voltages in one span of an simulation cycle; specifically, RVOLₜ={RVOL_{[0]}, RVOL_{[1]}, . . . , RVOL_{[K-1]}}ₜ, wherein RVOLₜ represents the average resetting voltage of the resetting operation from one span operation in the t-th simulation cycle of the memory unit, formula thereof is:

$${R VOL}_{t [ i ]} = \frac{1}{N} {\sum }_{m} {\{ {RVOL\_RAW}_{[ i ]}^{m} \}}_{t} .$$

Wherein i indicates the i-th memory unit, i∈[0, K−1]; j indicates the m-th resetting operation in one span, m∈[0, N−1]; t indicates the t-th simulation cycle or the t-th time slice in the simulation environment, t∈[0, T−1]; K is the total number of memory units in the RRAM chip, T is the number of simulation cycles covered by the raw data; N is the number of cycles of the completed setting-resetting cycle operations of memory unit in one span of simulation cycle.
3. Based on the preprocessed 9-dimensional data, the dataset D₁ with data structure K×9×T is constructed.

Specifically, the number of cycles T covered by the raw data is recorded as one training span, then each training span contains T time slices, constructing T matrices of K×9 in units of time slices as external input X of the model M, wherein X={X₀, X₁, . . . , X_{T-1}}, Xₜ={X_{[0]}, X_{[1]}, . . . , X_{[T-1]}}ₜ, Xₜ represents 9-dimensional data containing the K memory units in the t-th time slice.
4. The dataset D₁ is bicategory labeled of true failure or false failure to obtain the model training dataset D₂ comprising the external input Xₜ of model M and the corresponding label Cₜ; specifically, comprises the following steps.
(1) Judging the state result S_{t[i]} of the memory unit in the (t+1)-th simulation cycle according to the output result O_{t+1[i]} in each span of the (t+1)-th simulation cycle; the judgment basis is the following.
   a) when O_{t+1[i]} does not contain setting or resetting success, the state result S_{t+1[i]}=0, which indicates that the memory unit occurs true failure in the (t+1)-th simulation cycle;
   b) in all cases except for i, the state result S_{t+1[i]}=1, which indicates that the memory unit occurs false failure in the (t+1)-th simulation cycle.
(2) Labeling X_{t[i]} with the corresponding label

$${c}_{t [ i ]} = {[ {c}_{i}^{0} , {c}_{i}^{1} ]}_{t}$$

according to the state result S_{t+1[i]}; wherein the superscripts 0 and 1 are the index values of the two-dimensional vector; the labeling method is the following:
i. when the state result S_{t+1[i]}=0, the corresponding label of X_{t[i]} is c_{[i]}=[1, 0]ₜ;
ii. when the state result S_{t+1[i]}=1, the corresponding label of X_{t[i]} is c_{t[i]}=[0, 1]ₜ.
(3) Constructing T matrices of K×2 in units of time slices as the corresponding label Cₜ to the external input Xₜ of the model M, wherein Cₜ={C_{[0]}, C_{[1]}, . . . , C_{[K-1]}}ₜ; Xₜ and the corresponding label Cₜ form the model training data D_{2_t}, constructing T model training data D_{2_t} in units of time slices as the model training dataset D₂, wherein

$${D}_{2} = \{ {D}_{2 \_ 0} , {D}_{2 \_ 1} , {D}_{2 \_ T - 1} \} .$$

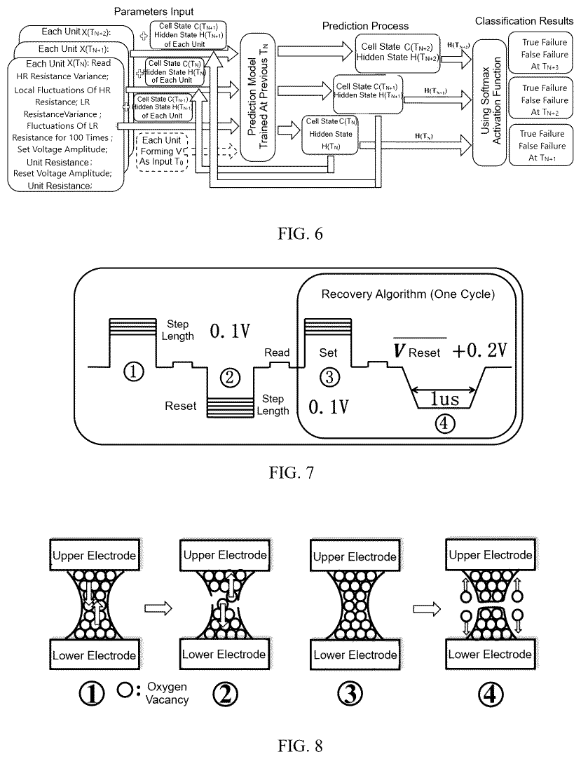

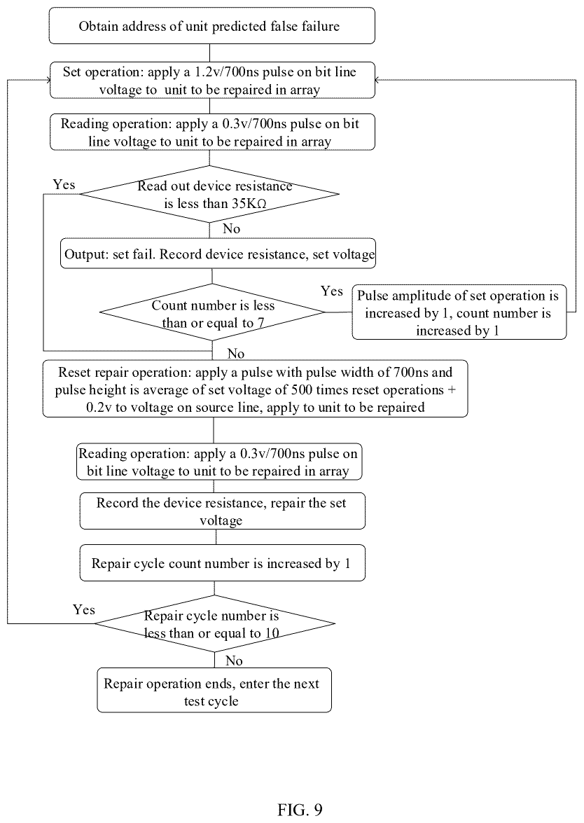

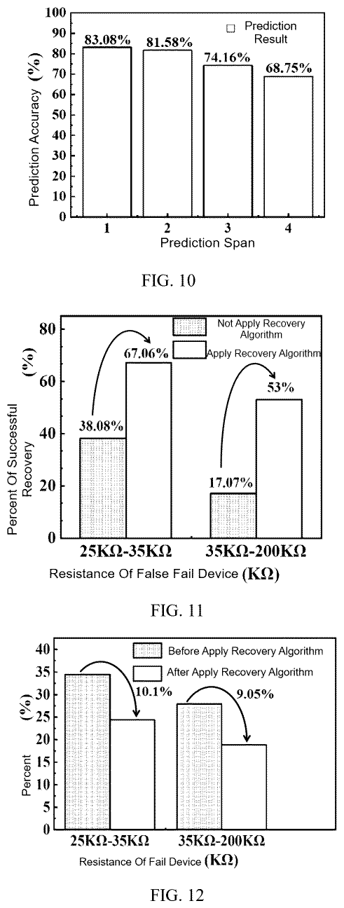

Specifically, the model M is constructed based on a long short-term memory neural network (LSTM), as shown in FIG. 6. The LSTM is used to predict important events with long interval and delay in time series. For a task of the service life prediction of the RRAM chip, model for the state changing process of the memory unit of the RRAM chip is built along the time axis, to define the events interval of the time series as time slice, wherein each time slice contains repeated read operations and setting operation, as well as setting-resetting cycle operations in one simulation cycle of all memory units of the RRAM chip under the simulation environment, or repeated read operations and setting operation as well as setting-resetting cycle operations in one erase-write period of each memory unit under the actual working conditions, to define the time slice when the device is just shipped out of the factory after the forming operation is T0, followed by T1, T2, . . . Tt, T(t+1), . . . .

The long short-term memory neural network (LSTM) can be seen as one cell (Cell) that iterates over time when performing calculations, the cell parameters comprises: cell state Cₜ, hidden state Hₜ and state update value Uₜ; wherein the cell state Cₜ is used to achieve the function of memory, and to involve the cumulative influence of the neural network input of the time slices before the current time slice into the current prediction; the hidden state Hₜ is used to calculate the prediction classification results of the current time slice and to update the neural network inputs of the next time slice; the state update value Uₜ is used to transform the neural network inputs of the current time slice into data that can be involved in neural network computation; the data structures of Cₜ, Hₜ and Uₜ are 200 dimensional vectors in this embodiment.

The long short-term memory neural network (LSTM) uses gate mechanism to control the information transfer, which contains three gates of forget gate FG, input gate IG and output gate OG respectively.

Specifically, the model M performing iterative computation comprises the following steps.
(1) Splitting the input data {D₂}ₜ of each time slice into K 9-dimensional vectors Xₜ={X_{[0]}, X_{[1]}, . . . , X_{[K-1]}}ₜ, which are input into K LSTM replica models M={M_{[0]}, M_{[1]}, . . . , X_{[K-1]}} with the same parameters respectively.
(2) Splicing the current external input X_{t[i]} of the current time slice Tₜ with the hidden state Hₜ₋₁ of the previous time slice Tₜ₋₁, to obtain the current neural network input Iₜ at the current time slice Tₜ, formula thereof is:

$${I}_{t} = \{ {H}_{t - 1} , {X}_{t [ i ]} \} .$$

(3) Performing affine transformation on the current neural network input Iₜ and then being activated by the tan h function, to obtain the current state update value Uₜ, formula thereof is:

$${U}_{t} = tanh ( {I}_{t} \times WC + BC )$$

Wherein WC is the weight of the affine transformation for Iₜ, BC is the offset of the affine transformation, the data structure of WC is a 209×200 matrix, the data structure of BC is a 200 dimensional vector in this embodiment.
(4) Multiplying the forget gate FG and the cell state Cₜ₋₁ of the previous time slice Tₜ₋₁ point by point, multiplying the input gate IG and the current update value Uₜ point by point, then adding the two product results to obtain the current cell state Cₜ, formula thereof is:

$${C}_{t} = FG \cdot {C}_{t - 1} + IG \cdot {U}_{t} .$$

Wherein FG=sigmoid(Iₜ×WF+BF), IG-sigmoid(I₁×WI+BI); WF, WI are the weights of the forget gate, the input gate for the affine transformation on the current input Iₜ at the current time slice Tₜ respectively; BF, BI are the offsets of the affine transformation of the forget gate, input gate respectively; the data structure of WF, WI are all 209×200 matrices, the data structure of BF, BI are 200 dimensional vectors in this embodiment.
(5) Activating the current cell state Cₜ by tan h and then being multiplied with the output gate OG point by point to obtain the current hidden state Hₜ;

$${H}_{t} = OG \cdot tanh ( {C}_{t} ) .$$

Wherein OG-sigmoid(Iₜ×WO+BO); WO is the weight of the affine transformation on the current input Iₜ at the current time slice Tₜ of the output gate; BO is the offset of the affine transformation of the output gate; the data structure of WO is a 209×200 matrix, the data structure of BO is a 200 dimensional vector in this embodiment.
(6) Inputting the current hidden state Hₜ into the neural network to enter cyclic computation of the next time slice Tₜ₊₁, repeating above steps (2)˜(5), meanwhile, the current hidden state Hₜ is affine transformed into two-dimensional space and activated by softmax function to obtain the current two-dimensional vector Pₜ, take the index value with larger value of the two elements in Pₜ as the current model output Y_{t[i]}, formula thereof is:

$${P}_{t} = [ {p}_{t}^{0} , {p}_{t}^{1} ] = softmax ( {H}_{t} \times WY + BY ) ;$$

$${Y}_{t [ i ]} = argmax ( {p}_{t}^{0} , {p}_{t}^{1} ) .$$

Wherein WI is the weight of the affine transformation on the current hidden state Hₜ; BY is the offset of the affine transformation, data structure thereof is a 2 dimensional vector; in this embodiment, the data structure of WY is a 200×2 matrix, the current model output Yₜ is the bicategory prediction result of whether or not the memory unit of the next time slice Tₜ₊₁ fails, Y_{t[i]}=1 indicates that the unit is predicted as false failure for the next time slice, Y_{t[i]}=0 indicates that the unit is predicted as true failure for the next time slice; the current two-dimensional vector

$${P}_{t} = [ {p}_{t}^{0} , {p}_{t}^{1} ] ,$$

represents the unit is true failure in the next time slice when Pₜ=[1, 0], that is, Y_{t[i]}=0; represents the unit is false failure in the next time slice when Pₜ=[0, 1], that is, Y_{t[i]}=1.
(7) Splicing the two-dimensional vector

$${P}_{t} = [ {p}_{t}^{0} , {p}_{t}^{1} ]$$

along the time dimension to form the output array P of K×TS×2; splicing the label array Cₜ along the time dimension to form the output array C of K×TS×2; comparing P with C, using the cross-entropy as the loss function, formula thereof is shown as following:

$$L = - \frac{1}{K} {\sum }_{t - 1}^{TS} {\sum }_{1}^{K} {[ {c}_{i}^{1} log {p}_{i}^{1} + {c}_{i}^{0} log {p}_{i}^{0} ]}_{t} .$$

Wherein TS is the training span, value thereof is the number of time slices covered by the training set Dₜᵣₐᵢₙ; K is the total number of memory units in the RRAM chip, the data structure of the label of a single memory unit is [c⁰, c¹], i indicates the i-th memory unit, t indicates the t-th time slice.

Back propagating the loss and updating the weights of the K LSTM replicas at the same time until the loss no longer decreases to obtain K trained LSTM replicas, selecting any one of the replicas as the final model M_{trained}; wherein M_{trained}={M_{trained_[0]}, M_{trained_[1]}, . . . , M_{trained_[K-1]}}; preferably, the Adam optimizer is used for back propagating as well as weights updating of the neural network.

Specifically, model training in step S120 comprises the following steps.
1. Dividing the model training dataset D₂ into training set Dₜᵣₐᵢₙ and test set Dₜₑₛₜ in units of time slices; wherein the data of the preceding TS time slices in D₂ are classified as training set, Dₜᵣₐᵢₙ={D_{2_0}, D_{2_1}, . . . , D_{2_TS-1}}, the data of the following T-TS time slices are classified as test set, Dₜₑₛₜ={D_{2_TS-1}, D_{2_TS}, . . . , D_{2_T-1}}; preferably, the value of T is 25, the value of TS is 20.
2. Initializing the model M, setting the initial values of the cell state and hidden state of the LSTM to 0; constructing M into K LSTM replica models {M_{[0]}, M_{[1]}, . . . , M_{[K-1]}} with the same parameters.
3. Splitting the input data {D₂}ₜ of each time slice in Dₜᵣₐᵢₙ into K 9-dimensional vectors Xₜ={X_{[0]}, X_{[1]}, . . . , X_{[K-1]}}ₜ, inputting the split data into K LSTM replica models M={M_{[0]}, M_{[1]}, . . . , X_{[K-1}]} with the same parameters in sequence of the time slices respectively, to complete the model training and obtain the K trained replica models, selecting any one of the replicas as the final model M_{trained}, using Dₜₑₛₜ to test M_{trained}.

Specifically, the obtaining the actually measured data of each memory unit to complete read-write operations of one erase-write period in the actual erase-write process in step S130 comprises the following steps.
(1) Obtaining the forming voltage FVₚ for the forming operation of a completely new RRAM chip.
(2) Recording the actually measured data of each memory unit in each erase-write period under the normal working state of the formed RRAM chip; wherein one erase-write period comprises: the memory unit completes the setting/resetting cyclic operations of preset cycle times N, which is recorded as one span within the erase-write period; after completing one span operation within the erase-write period, repeated read operations of preset times n and then one time resetting operation are performed to the memory unit, then repeated read operations of preset times n is performed again; the actually measured data Dₚₜ comprises: setting voltage SVOL_RAW_{p[i]} and resetting voltage RVOL_RAW_{p[i]}, setting resistance SR_RAW_{p[i]} and resetting resistance RR_RAW_{p[i]} recorded within one span of the erase-write period, resetting resistance sample R_{pr[i]} recorded by the first repeated read operation in the erase-write period, setting resistance sample R_{ps[i]} recorded by the second repeated read operation in the erase-write period, setting resistance R_{pset[i]} and setting voltage V_{pset[i]} recorded between two repeated read operations, as well as all the output results O_{p[i]} of the erase-write period; specifically comprises the following steps.
i. Writing the following data into the flash memory on the periphery of the RRAM chip in real time: the resistance {RVOL_RAW_{p[i]}}ₜ and the corresponding setting voltage {SVOL_RAW_{p[i]}}ₜ of each memory unit when the memory unit is setting success in one span of the erase-write period t, or the resistance {RVOL_RAW_{p[i]}}ₜ and the corresponding setting voltage {SVOL_RAW_{p[i]}}ₜ of each memory unit when setting reaches the preset times and still is unsuccessful; as well as the resistance {RR_RAW_{p[i]}}ₜ and the corresponding resetting voltage {RVOL_RAW_{p[i]}}ₜ of each memory unit when resetting success, or the resistance {RR_RAW_{p[i]}}ₜ and the corresponding resetting voltage {RVOL_RAW_{p[i]}}ₜ of each memory unit when resetting reaches the preset times and still is unsuccessful; as well as the output result {O_{p[i]}}ₜ; wherein the successful setting comprises the setting being successful at one time or the setting being successful by gradual setting before not reaching the preset times, the output result O is setting success; the successful resetting comprises the resetting being successful at one time or the resetting being successful by gradual resetting before not reaching the preset times, the output result O is resetting success.
ii. Writing the following data into the flash memory on the periphery of the RRAM chip: the resetting resistance sample {R_{pr[i]}}ₜ recorded by the first repeated read operation in the completion of the erase-write period of the memory unit, the setting resistance sample {R_{ps[i]}}ₜ recorded by the second repeated read operation in the erase-write period, the setting resistance {R_{pset[i]}}ₜ and setting voltage {V_{pset[i]}}ₜ recorded between the two repeated operations as well as all the output results {O_{p[i]}}ₜ in the erase-write period.

Specifically, the preprocessing the actually measured data to obtain the nine dimensional input data X_{pt[i]}={FV_{p[i]}, SR_{p[i]}, RR_{p[i]}, SF_{p[i]}, RF_{p[i]}, SVAR_{p[i]}, RVAR_{p[i]}, SVOL_{p[i]}, RVOL_{p[i]}}ₜ of the memory unit in current erase-write period t in step S130 comprises the following steps.
(1) FV_{pt[i]} represents the forming voltage of the memory unit, the value of the first erase-write period is the forming voltage FVₚ of the chip, the values of the subsequent erase-write periods are all set to 0; the time slice corresponds to the erase-write period of the memory unit to be predicted; specifically,

$$F {V}_{pt [ i ]} = \{ \begin{matrix}F V , & t = 0 \\ 0 , & t > 0\end{matrix} ;$$

wherein, t=0 is the first time slice, corresponding to the first erase-write period of the memory unit, FV_{p0[i]}=FV=1.7 v; when t∈[1, TS−1] is the second to the (TS−1)-th time slices, corresponding to the second to the (TS−1)-th erase-write period of the memory unit, that is FV_{pt[i]}={FV_{p[1]}, FV_{p[2]}, . . . , FV_{p[K-1]}}ₜ=0.
(2) SR_{pt[i]} represents the normalized setting resistance of the memory unit, which is obtained through dividing an average value of the original setting resistance SR_RAW_{pt[i]} by the stable low resistance R_{low} of the RRAM; wherein R_{low} is the low resistance of the memory unit when the RRAM chip is working normally, which is also the low resistance under the most stable state, formula thereof is:

$${SR}_{pt [ 1 ]} = \frac{1}{N} \frac{1}{{R}_{low}} {\sum }_{j} {\{ {SR\_RAW}_{p [ i ]}^{j} \}}_{t} .$$

Wherein i indicates the i-th memory unit, i∈[0, K−1]; j indicates the j-th setting operation in one span of the erase-write period, j∈[0, N−1]; t indicates the t-th time slice corresponding to the current erase-write period, K is the total number of memory units in the RRAM chip; N is the number of cycles of the completed setting-resetting cycle operations of memory unit in one span of the erase-write period.
(3) RR_{pt[i]} represents the normalized resetting resistance of the memory unit, which is obtained through dividing an average value of the original resetting resistance RR_RAW_{pt[i]} by the stable high resistance R_{high} of the RRAM; wherein R_{high} is the high resistance of the memory unit when the RRAM chip is working normally, which is also the high resistance under the most stable state; formula thereof is:

$${RR}_{pt [ i ]} = \frac{1}{N} \frac{1}{{R}_{high}} {\sum }_{m} {\{ {RR\_RAW}_{p [ i ]}^{m} \}}_{t} .$$

Wherein i indicates the i-th memory unit, i∈[0, K−1]; j indicates the j-th setting operation in one span of the erase-write period, j∈[0, N−1]; t indicates the t-th time slice corresponding to the current erase-write period; K is the total number of memory units in the RRAM chip; N is the number of cycles of the completed setting-resetting cycle operations of memory unit in one span of the erase-write period.
(4) SF_{pt[i]} represents the local fluctuations of the setting resistance of the memory unit, which is obtained by normalizing the setting resistance samples and then performing convolution summation with a one-dimensional edge detection operator [−1, 0, 1]; formula thereof is:

$${R}_{{ps}^{′} t [ i ]} = {R}_{pst [ i ]} / {R}_{low} ;$$

$$δ = [ - 1 , 0 , 1 ] ;$$

$${SF}_{pt [ i ]} = \sum δ ⊗ {\{ {R}_{{ps}^{′} [ i ]} \}}_{t} .$$

Wherein

$${R}_{ps [ i ]} = \{ {R}_{ps [ i ]}^{0} , {R}_{ps [ i ]}^{1} , … , {R}_{ps [ i ]}^{n - 1} \} t ,$$

t indicates the t-th time slice corresponding to the current erase-write period; K is the total number of memory units in the RRAM chip, TS is the number of time slices covered by the training set of the training model; n is the number of samples of the setting resistance R_{pst[i]} obtained by repeated read operations after one span in the erase-write period.
(5) RF_{pt[i]} represents the local fluctuations of the resetting resistance of the memory unit, which is obtained by normalizing the resetting resistance samples and then performing convolution summation with a one-dimensional edge detection operator [−1, 0, 1]; formula thereof is:

$${R}_{{pr}^{′} t [ i ]} = {R}_{prt [ i ]} / {R}_{high} ;$$

$$δ = [ - 1 , 0 , 1 ] ;$$

$${RF}_{pt [ i ]} = \sum δ ⊗ {\{ {R}_{{pr}^{′} [ i ]} \}}_{t} .$$

Wherein

$${R}_{prt [ 1 ]} = \{ {R}_{pr [ i ]}^{0} , {R}_{pr [ i ]}^{1} , … , {R}_{pr [ i ]}^{n - 1} \} t ;$$

t indicates the t-th time slice corresponding to the current erase-write period; K is the total number of memory units in the RRAM chip, TS is the number of time slices covered by the training set of the training model; n is the number of samples of the resetting resistance R_{rt[i]} obtained by repeated read operations after one span in the erase-write period.
(6) SVAR_{pt[i]} represents the global fluctuations of the setting resistance of the memory unit, which is obtained by normalizing each resistance in the setting resistance samples and then calculating variance thereof; formula thereof is:

$${R}_{{ps}^{′} t [ i ]} = {R}_{pst [ i ]} / {R}_{low} ;$$

$${SVAR}_{pt [ i ]} = {\{ \frac{{\sum }_{k} {( {R}_{{ps}^{′} [ i ]}^{k} - \frac{{\sum }_{k} {R}_{{ps}^{′} [ i ]}^{k}}{n} )}^{2}}{n} \}}_{t} .$$

Wherein,

$${R}_{pst [ i ]} = \{ {R}_{ps [ 1 ]}^{0} , {R}_{ps [ 1 ]}^{1} , … , {R}_{ps [ 1 ]}^{n - 1} \} t ;$$

t indicates the t-th time slice corresponding to the current erase-write period; K is the total number of memory units in the RRAM chip; k indicates the k-th read operation from the n number of continuous read operations after one setting operation, wherein the one setting operation is after the n continuous read operations after one span in each erase-write period of the memory unit; n is the number of samples of the setting resistance R_{pst[i]} obtained by repeated read operations after one span in the erase-write period.
(7) RVAR_{t[i]} represents the global fluctuations of the resetting resistance of the memory unit, which is obtained by normalizing each resistance in the resetting resistance samples and then calculating variance thereof, formula thereof is:

$${R}_{{pr}^{′} t [ i ]} = {R}_{prt [ i ]} / {R}_{high} ;$$

$${RVAR}_{pt [ i ]} = {\{ \frac{{\sum }_{1} {( {R}_{{pr}^{′} [ i ]}^{1} - \frac{{\sum }_{1} {R}_{{pr}^{′} [ i ]}^{1}}{n} )}^{2}}{n} \}}_{t} .$$

Wherein

$${R}_{{prt [ i ]}^{=}} \{ {R}_{pr [ i ]}^{0} , {R}_{pr [ i ]}^{1} , … , {R}_{pr [ i ]}^{n - 1} \} t ;$$

t indicates the t-th time slice corresponding to the current erase-write period; K is the total number of memory units in the RRAM chip; I indicates the I-th read operation from the n continuous read operations after one span in each erase-write period of the memory unit; n is the number of samples of the resetting resistance R_{rt[i]} obtained by repeated read operations after one span in the erase-write period.
(8) SVOL_{pt[i]} represents the average setting voltage of the memory unit, which is obtained by averaging all the recorded setting voltages in one span of the erase-write period, formula thereof is:

$${SVOL}_{pt [ i ]} = \frac{1}{N} {\sum }_{J} {\{ {SVOL\_RAW}_{p [ i ]}^{j} \}}_{t} .$$

Wherein i indicates the i-th memory unit, i∈[0, K−1]; j indicates the j-th setting operation in one span, j∈[0, N−1]; t indicates the t-th time slice corresponding to the current erase-write period; K is the total number of memory units in the RRAM chip; N is the number of cycles of the completed setting-resetting cycle operations of memory unit in one span of the erase-write period.
(9) RVOL_{pt[i]} represents the average resetting voltage of the memory unit, which is obtained by averaging all the recorded resetting voltages in one span of the erase-write period, formula thereof is:

$${RVOL}_{pt [ i ]} = \frac{1}{N} {\sum }_{m} {\{ {RVOL\_RAW}_{p [ i ]}^{m} \}}_{t} .$$

Wherein i indicates the i-th memory unit, i∈[0, K−1]; m indicates the m-th resetting operation in one span, m∈[0, N−1]; t indicates the t-th time slice corresponding to the current erase-write period; K is the total number of memory units in the RRAM chip; N is the number of cycles of the completed setting-resetting cycle operations of memory unit in one span of the erase-write period.

Specifically, the inputting X_{pt[i]} into the corresponding trained model M_{trained} to obtain a prediction result Y_{t[i]} of the memory unit for the next erase-write period t+1, and finally determine whether or not it is a false failure memory unit that actually needs to be repaired in step S130 comprises the following steps.
(1) Inputting the preprocessed data X_{pt[i]} into the trained model M_{trained} after one erase-write period.
(2) M_{trained[i]} outputting Y_{t[i]} as the prediction result of the memory unit in the next erase-write period t+1; wherein when Y_{t[i]}=1 indicates that the unit is predicted as false failure for the next time slice, to execute the following step (3); when Y_{t[i]}=0 indicates that the unit is predicted as true failure for the next time slice, to transfer the data stored in it to other memory units.
(3) Making a secondary judgment on the prediction result of Y_{t[i]}=1, when the output result O_{t[i]} of the memory unit in current erase-write period t contains N+1 successful setting and N successful resetting, it is judged that the memory unit does not need to be repaired; otherwise, the memory unit is a false failure memory unit that actually needs to be repaired, carrying out the repair operation via digital-to-analog converter circuit.

Specifically, the performing repair operation on the memory unit in step S140 comprises the following steps.
(1) Gradually setting: for the i-th memory unit to be repaired, applying the setting pulse at the terminal of bit line thereof to perform the setting operation, then performing the read operation to read out resistance thereof; when the read out resistance is less than the stable low resistance R_{low} of the RRAM chip, it means that the setting operation is successful, to execute the following step (2); otherwise, increasing the pulse amplitude of the setting operation gradually in the preset increase value, repeating the setting and read operation cycles until the setting and read operations reach the preset cycle times or the resistance read out by the read operation is less than the stable low resistance R_{low} of the RRAM chip; wherein the stable low resistance R_{low} is the low resistance of the memory unit when the RRAM chip is working normally, and also is the low resistance under the most stable state; wherein the read operation pulse is 0.3 v/700 ns, the initial setting pulse is 1.2 v/700 ns, the value of R_{low} is 35 kΩ; optionally, when the resistance read out by the read operation after the setting operation is greater than or equal to the stable low resistance R_{low} of the RRAM chip, output setting fail; optionally, the preset increase value is 0.05 v˜0.5 v; preferably, the preset increase value is 0.1 v, the preset number of cycles is 8 times.
(2) Resetting repair: for the i-th memory unit to be repaired, applying the resetting pulse higher than the average resetting voltage of the current erase-write period at the terminal of source line thereof to perform the resetting operation, then perform the read operation to read out resistance thereof; the amplitude of the resetting pulse voltage is RVOL_{pt[i]}+the preset increase value; wherein RVOL_{pt[i]} is the average voltage of N resetting operations of the memory unit within one span of the current erase-write period; wherein the read operation pulse is 0.3 v/700 ns, the initial setting pulse is 1.2 v/700 ns; optionally, the preset increase value may be 0.1 v˜0.3 v; preferably the preset increase value is 0.2 v.
(3) Repeating repair cycle of above steps (1) and (2) until the cumulative preset number of repair cycles is reached to complete the repair operation of the memory unit; optionally, the preset number of the repair cycles is 5˜15 times; preferably, the cumulative preset number of the repair cycles is 10.

Compared with existing technology, the present application can achieve at least one of the following beneficial effects.
1. The prediction accuracy rate of the model constructed using the method provided by the present application reaches 86.75%, which is much higher than 65% of the existing prediction model; at the same time, compared with the drawback of the existing model that has too many setting/resetting operations in one prediction cycle, the model of the present application realizes the prediction of the memory unit under fewer number of setting/resetting operations. That is, one prediction cycle of the existing model needs to include 100,000 setting/resetting operations, while the model of the present application can reduce the prediction cycles to 500 setting/resetting operations, which can achieve prediction and repair of the memory unit more timely.
2. The model input using nine-dimensional data, wherein the three parameters SVOLₜ, RVOLₜ, FVₜ, which are related to voltage, contain the key external operation information of the RRAM chip, the six parameters SRₜ, RRₜ, SFₜ, RFₜ, SVARₜ, RVARₜ, which are related to resistance, contain the main physical state information of the memory unit of the RRAM chip, which fits well with a physical model of the RRAM resistive variation process, the time series model constructed based on them is more scientific and effective; wherein two sets of feature quantities SFₜ/RFₜ, SVARₜ/RVARₜ are used to represent the local fluctuations and global fluctuations of the resistance respectively, the random fluctuations and jumping properties of the resistance of the RRAM is included in the inputs of the model, so the physical state of the RRAM device is reflected more comprehensively.
3. According to the prediction results of the model, a specific voltage excitation is applied to the memory unit which may occur false failure and the amplitude of the voltage is gradually increased to prevent the occurrence of false failure. Compared with the existing way of remedying false failure after it has occurred in the memory unit and the remedy way of simply increasing the voltage and the storage window, the method provided by the present application will not accelerate the aging of the memory unit and reduce the service life of the memory unit due to the excessively high voltage, and can significantly reduce the error rate of the memory unit of RRAM chip.

A person skilled in the art can understand that all or part of the process of implementing the methods of the above embodiments may be implemented by related hardware according to an instruction from a computer program, and the program may be stored in a computer-readable storage medium, wherein the computer-readable storage medium is a magnetic disc, an optical disc, a read-only memory, a random access memory and so on.

The above are merely preferable particular embodiments of the present application, and the protection scope of the present application is not limited thereto. All of the variations or substitutions that a person skilled in the art can easily envisage within the technical scope disclosed by the present application should fall within the protection scope of the present application.

1. A service life prediction and repair method for resistive random access memory (RRAM) chip, wherein the method comprises the following steps:
constructing a model training dataset, the dataset comprises: input data Xₜ and bicategory labeling of true failure or false failure; wherein the input data Xₜ comprises a forming voltage FVₜ, a normalized setting resistance SRₜ, a normalized resetting resistance RRₜ, local fluctuations of a setting resistance SFₜ, local fluctuations of a resetting resistance RFₜ, global fluctuations of the setting resistance SVARₜ, global fluctuations of the resetting resistance RVARₜ, an average setting voltage SVOLₜ and an average resetting voltage RVOLₜ;
training a model M by the constructed training dataset, the model M comprises K LSTM replica models {M_{[0]}, M_{[1]}, . . . , M_{[K-1]}} with the same parameters; the different replica models are used for independent forward inference and error computation for K memory units;
obtaining actually measured data of each memory unit to be predicted to complete read and write operations for one erase-write period under a normal working state; processing the actually measured data to obtain input data X_{pt[i]}; inputting the input data X_{pt[i]} into the corresponding trained model, to obtain a prediction result Y_{t[i]} of the memory unit for a next erase-write period t+1, and finally determine whether or not it is a false failure memory unit that actually needs to be repaired;
obtaining an address of the false failure memory unit that actually needs to be repaired; performing repair operation on the false failure memory unit.

2. The method according to claim 1, wherein the constructing a model training dataset comprises:
obtaining raw data Dₜ;
preprocessing the raw data to obtain the input data Xₜ={FVₜ, SRₜ, RRₜ, SFₜ, RFₜ, SVARₜ, RVARₜ, SVOLₜ, RVOLₜ}, which comprises nine dimensions;
constructing the dataset D₁ with data structure K×9×T based on the preprocessed 9-dimensional data; wherein K is the total number of memory units in the RRAM chip; T is the number of simulation cycles covered by the raw data;
bicategory labeling the dataset D₁ as true failure or false failure to obtain the model training dataset D₂ comprising an external input Xₜ of the model M and a corresponding label Cₜ.

3. The method according to claim 2, wherein the obtaining the raw data comprises:
(1) performing forming operation on the RRAM chip to turn each memory unit in the chip into conduction (ON) state, and recording the forming operation voltage FV;
(2) verifying the forming effect and recording a forming resistance R_{f} and an output result O of each memory unit;
(3) performing setting operation on the formed chip, recording a resistance SR_RAW and a corresponding setting voltage SVOL_RAW, as well as the output result O of each memory unit when setting is successful, or recording the resistance SR_RAW and the corresponding setting voltage SVOL_RAW, as well as the output result O of each memory unit when the setting reaches the preset times and still is unsuccessful; wherein the successful setting comprises setting success at one time, or setting success by gradually setting before not reaching the preset times;
(4) performing resetting operation on the set chip, recording a resistance RR_RAW and a corresponding resetting voltage RVOL_RAW, as well as the output result O of each memory unit when the resetting is successful, or recording the resistance RR_RAW and the corresponding resetting voltage RVOL_RAW, as well as the output result O of each memory unit when the resetting reaches the preset times and still is unsuccessful;
(5) repeating the setting and resetting operations to complete the preset cycles N within one span, wherein the cycle of above steps (3) and (4) is repeated, to complete the preset cycles and record as completion of one span, then performing the following step (6);
(6) repeating read operation of preset times n, which is performed on the chip memory array to obtain resetting resistance sample Rᵣ for calculating fluctuations of resetting resistance;
(7) performing setting operation on the chip, recording resistance Rₛₑₜ and current setting voltage Vₛₑₜ, as well as the output result O of each memory unit when the setting is successful, or recording the resistance Rₛₑₜ and the current setting voltage Vₛₑₜ, as well as output result O of each memory unit when the setting reaches the preset times and still is unsuccessful;
(8) repeating read operation of the preset times n to obtain setting resistance sample Rₛ for calculating fluctuations of setting resistance;
(9) recording above steps (3)˜(8) as one simulation cycle, repeating T simulation cycles to obtain the raw data Dₜ={FV, SVOL_RAW, RVOL_RAW, SR_RAW, RR_RAW, Rᵣ, Rₛ, Rₛₑₜ, Vₛₑₜ}ₜ.

4. The method according to claim 1, wherein the input data Xₜ comprises:
(1) FVₜ represents the forming voltage, a value of a first time slice is FV in the raw data, all subsequent time slices are set to 0;
(2) SRₜ represents the normalized setting resistance, which is obtained through dividing an average value of the original setting resistance SR_RAW by stable low resistance R_{low} of the RRAM; wherein R_{low} is the low resistance of the memory unit when the RRAM chip is working normally, which is also the low resistance under the most stable state;
(3) RRₜ represents the normalized resetting resistance, which is obtained through dividing an average value of the original resetting resistance RR_RAW by stable high resistance R_{high} of the RRAM; wherein R_{high} is the high resistance of the memory unit when the RRAM chip is working normally, which is also the high resistance under the most stable state;
(4) SFₜ represents the local fluctuations of the setting resistance of the memory unit, which is obtained by normalizing setting resistance samples and then performing convolution summation with a one-dimensional edge detection operator [−1, 0, 1];
(5) RFₜ represents the local fluctuations of the resetting resistance of the memory unit, which is obtained by normalizing resetting resistance samples and then performing convolution summation with the one-dimensional edge detection operator [−1, 0, 1];
(6) SVARₜ represents the global fluctuations of the setting resistance of the memory unit, which is obtained by normalizing each resistance in the setting resistance samples and then calculating variance thereof;
(7) RVARₜ represents the global fluctuations of the resetting resistance of the memory unit, which is obtained by normalizing each resistance in the resetting resistance samples and then calculating variance thereof;
(8) SVOLₜ represents the average setting voltage of the memory unit, which is obtained by averaging all the recorded setting voltages in one span of a simulation cycle;
(9) RVOLₜ represents the average resetting voltage of the memory unit, which is obtained by averaging all the recorded resetting voltages in one span of a simulation cycle.

5. The method according to claim 1, wherein the bicategory labeling of true failure or false failure comprises:
(1) judging a state result S_{t[i]} of the memory unit in a t+1st simulation cycle according to output result O_{t+1[i]} in each span of the t+1st simulation cycle; judgment basis is following:
a) when O_{t+1[i]} does not contain setting or resetting success, the state result S_{t+1[i]}=0, which indicates that the memory unit occurs true failure in the t+1st simulation cycle;
b) in all cases except for i, the state result S_{t+1[i]}=1, which indicates that the memory unit occurs false failure in the t+1st simulation cycle;
(2) labeling X_{t[i]} with the corresponding label
$${c}_{t [ i ]} = {[ {c}_{i}^{0} , {c}_{i}^{1} ]}_{t}$$
according to the state result S_{t+1[i]}; wherein the superscripts 0 and 1 thereof are index values of the two-dimensional vector; the labeling method is the following:
i. when the state result S_{t+1[i]}=0, a corresponding label of X_{t[i]} is c_{t[i]}=[1, 0]ₜ;
ii. when the state result S_{t+1[i]}=1, the corresponding label of X_{t[i]} is c_{t[i]}=[0, 1]ₜ;
(3) constructing T matrices K×2 in units of time slices as the corresponding label Cₜ of the external input Xₜ of the model M, wherein Cₜ={C_{[0]}, C_{[1]}, . . . , C_{[K-1]}}ₜ; the model training data D_{2_t} consists of the Xₜ and the corresponding label Cₜ, constructing T model training data D_{2_t} in units of time slices as the model training dataset D₂, wherein D₂={D_{2_0}, D_{2_1}, D_{2_T-1}}.

6. The method according to claim 1, wherein the model M comprises:
constructing the model M based on the LSTM, the cell parameters comprise cell state Cₜ, hidden state Hₜ and state update value Uₜ; the control gates comprise: forget gate FG, input gate IG and output gate OG, and formulae thereof respectively are:
$$FG = sigmoid ( {I}_{t} \times WF + BF ) ;$$
$$IG = sigmoid ( {I}_{t} \times WI + BI ) ;$$
$$OG = sigmoid ( {I}_{t} \times WO + BO ) ;$$
wherein WF, WI, WO are weights of the forget gate, the input gate, the output gate for the affine transformation on the current neural network input Iₜ at current time slice respectively; BF, BI, BO are offsets of the affine transformation of the forget gate, the input gate, the output gate respectively.

7. The method according to claim 6, wherein the iterative computation of the model M comprises the following steps:
(1) splitting the input data {D₂}ₜ of each time slice into K 9-dimensional vectors, which are input into K LSTM replica models with the same parameters respectively;
(2) splicing a current external input X_{t[i]} of a current time slice Tₜ with a hidden state Hₜ₋₁ of a previous time slice Tₜ₋₁ to obtain a current neural network input Iₜ at the current time slice Tₜ;
(3) affine transforming on the current neural network input Iₜ, then activating by tanh function to obtain a current state update value Uₜ;
(4) multiplying the forget gate FG and the cell state Cₜ₋₁ of the previous time slice Tₜ₋₁ point by point, multiplying the input gate IG and the current state update value Uₜ point by point, then adding above two product results to obtain a current cell state Cₜ;
(5) activating the current cell state Cₜ by tan h, then being multiplied with the output gate OG point by point to obtain a current hidden state Hₜ;
(6) inputting the current hidden state Hₜ into the neural network to enter cyclic computation of a next time slice Tₜ₊₁, repeating above steps (2)˜(5), meanwhile, affine transforming the current hidden state Hₜ into two-dimensional space and being activated by softmax function to obtain a current two-dimensional vector Pₜ, taking the index value with larger value of two elements in Pₜ as a current model output Y_{t[i]};
(7) splicing the two-dimensional vector Pₜ along time dimension to form an output array P of K×TS×2; splicing the label array Cₜ along the time dimension to form an output array C of K×TS×2; comparing P with C, using cross-entropy as a loss function, formula thereof is the following:
$$L = - \frac{1}{K} {\sum }_{t = 1}^{TS} {\sum }_{i = 1}^{K} {[ {c}_{i}^{1} log {p}_{i}^{1} + {c}_{i}^{0} log {p}_{i}^{0} ]}_{t} ;$$
wherein TS is a training span, value thereof is the number of time slices covered by the training set Dₜᵣₐᵢₙ; K is the total number of memory units in the RRAM chip, data structure of a label of a single memory unit is [c⁰, c¹], i indicates the i-th memory unit, t indicates the t-th time slice;
back propagating the loss and updating weights of the K LSTM replicas at the same time until the loss no longer decreasing, to obtain K trained LSTM replicas, selecting any one of the replicas as a final model M_{trained}; wherein M_{trained=}{M_{trained_[0]}, M_{trained_[1]}, . . . , M_{trained_[K-1]}}; preferably, a Adam optimizer is used for back propagating as well as weights updating of the neural network.

8. The method according to claim 1, wherein the actually measured data, comprising:
(1) obtaining the forming voltage FVₚ for the forming operation of a completely new RRAM chip;
(2) recording the actually measured data of each memory unit in each erase-write period under a normal working state of the formed RRAM chip; wherein one erase-write period comprises: the memory unit completes setting/resetting cyclic operations of preset cycle times N, which are recorded as one span within the erase-write period; after completing one span operation within the erase-write period, performing the following steps to the memory unit: repeating read operation of preset times n, then one time setting operation, repeating read operation of the preset times n again; the actually measured data Dₚₜ comprises: setting voltage SVOL_RAW_{p[i]} and resetting voltage RVOL_RAW_{p[i]} recorded within one span of the erase-write period, setting resistance SR_RAW_{p[i]} and resetting resistance RR_RAW_{p[i]}, resetting resistance sample R_{pr[i]} recorded by the first repeating read operation of the erase-write period, setting resistance sample R_{ps[i]} recorded by the second repeating read operation of the erase-write period, setting resistance R_{pset[i]} and setting voltage V_{pset[i]} recorded between two repeating read operations, as well as all the output results O_{p[i]} of the erase-write period.

9. The method according to claim 1, wherein the processing the actually measured data to obtain input data comprises:
(1) FV_{pt[i]} represents the forming voltage of the memory unit, the value of the first erase-write endurance cycle is the forming voltage FVₚ of the chip, the values of the subsequent erase-write endurance cycles are all set to 0;
(2) SR_{pt[i]} represents the normalized setting resistance of the memory unit, which is obtained through dividing an average value of the original setting resistance SR_RAW_{pt[i]} by stable low resistance R_{low} of the RRAM;
(3) RR_{pt[i]} represents the normalized resetting resistance of the memory unit, which is obtained through dividing an average value of the original resetting resistance RR_RAW_{pt[i]} by stable high resistance R_{high} of the RRAM;
(4) SF_{pt[i]} represents the local fluctuations of the setting resistance of the memory unit, which is obtained by normalizing the setting resistance samples, then performing convolution summation with a one-dimensional edge detection operator [−1, 0, 1];
(5) RF_{pt[i]} represents the local fluctuations of the resetting resistance of the memory unit, which is obtained by normalizing the resetting resistance samples, then performing convolution summation with the one-dimensional edge detection operator [−1, 0, 1];
(6) SVAR_{pt[i]} represents the global fluctuations of the setting resistance of the memory unit, which is obtained by normalizing each resistance in the setting resistance samples, then calculating variance thereof;
(7) RVAR_{t[i]} represents the global fluctuations of the resetting resistance of the memory unit, which is obtained by normalizing each resistance in the resetting resistance samples, then calculating variance thereof;
(8) SVOL_{pt[i]} represents the average setting voltage of the memory unit, which is obtained by averaging all the recorded setting voltages in one span of the erase-write endurance cycle;
(9) RVOL_{pt[i]} represents the average resetting voltage of the memory unit, which is obtained by averaging all the recorded resetting voltages in one span of the erase-write period.

10. The method according to claim 1, wherein the determining whether or not it is a false failure memory unit that actually needs to be repaired comprising:
(1) the preprocessed data X_{pt[i]} after one erase-write period is input into the trained model M_{trained};
(2) M_{trained[i]} outputs Y_{t[i]} as a prediction result of the memory unit in the next erase-write period t+1; wherein when Y_{t[i]}=1 indicates that the unit is predicted as false failure for the next time slice, executing the following step (3); when Y_{t[i]}=0 indicates that the unit is predicted as true failure for the next time slice, transferring the data stored in it to other memory units; and
(3) the prediction result of Y_{t[i]}=1 is made a secondary judgment, when the output result O_{t[i]} of the memory unit in current erase-write period t contains N+1 setting success and N resetting success, it is judged that the memory unit does not need to be repaired; otherwise, the memory unit is a false failure memory unit that actually needs to be repaired, the repair operation is carried out by a digital-to-analog converter circuit.

11. The method according to claim 1, wherein the repair operation comprises:
(1) gradually setting: for the i-th memory unit to be repaired, applying setting pulse at the terminal of bit line thereof to perform the setting operation, then performing the read operation to read out resistance thereof; when the read out resistance is less than the stable low resistance R_{low} of the RRAM chip, it means that the setting operation is successful to execute the following step (2); otherwise, increasing a pulse amplitude of the setting operation gradually in a preset increase value, repeating the setting and read operation cycles until the setting and read operations reach the preset cycle times or the resistance read out by the read operation is less than the stable low resistance R_{low} of the RRAM chip;
(2) resetting repair: for the i-th memory unit to be repaired, applying the resetting pulse higher than the average resetting voltage of the current erase-write period at the terminal of source line thereof to perform the resetting operation, then performing the read operation to read out resistance thereof; the amplitude of the resetting pulse voltage is RVOL_{pt[i]}+the preset increase value; wherein RVOL_{pt[i]} is the average voltage of N resetting operations of the memory unit within a span of the current erase-write period;
(3) repeating the repair cycle of above steps (1) and (2), until the cumulative preset number of repair cycles is reached to complete the repair operation of the memory unit.

12. A non-transitory machine-readable storage medium comprising instructions that when executed cause a processor of a computing device to:
constructing a model training dataset, the dataset comprises: input data Xt and bicategory labeling of true failure or false failure; wherein the input data Xt comprises a forming voltage FVt, a normalized setting resistance SRt, a normalized resetting resistance RRt, local fluctuations of a setting resistance SFt, local fluctuations of a resetting resistance RFt, global fluctuations of the setting resistance SVARt, global fluctuations of the resetting resistance RVARt, an average setting voltage SVOLt and an average resetting voltage RVOLt;
training a model M by the constructed training dataset, the model M comprises K LSTM replica models {M[0], M[1], . . . , M[K−1]} with the same parameters; the different replica models are used for independent forward inference and error computation for K memory units;
obtaining actually measured data of each memory unit to be predicted to complete read and write operations for one erase-write period under a normal working state; processing the actually measured data to obtain input data Xpt[i]; inputting the input data Xpt[i] into the corresponding trained model, to obtain a prediction result Yt[i] of the memory unit for a next erase-write period t+1, and finally determine whether or not it is a false failure memory unit that actually needs to be repaired;
obtaining an address of the false failure memory unit that actually needs to be repaired; performing repair operation on the false failure memory unit.
